(19) United States
(12) Patent Application Publication
(10) Pub. No.: US 2026/0179522 A1
(43) Pub. Date: Jun. 25, 2026

(54) SHIFT REGISTER UNIT, DISPLAY PANEL, DRIVING METHOD THEREOF AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Changchang LIU, Beijing (CN); Haoyu LI, Beijing (CN); Yuxiao LI, Beijing (CN); Yipeng CHEN, Beijing (CN); Ling SHI, Beijing (CN)

(21) Appl. No.: 18/840,428

(22) PCT Filed: Sep. 26, 2023
(86) PCT No.: PCT/CN2023/121535

§ 371 Date: Aug. 21, 2024

(51) Int. Cl. G09G 3/20; G11C 19/28

(52) U.S. Cl. CPC G09G 3/2092; G09G 2300/0408; G09G 2310/0267; G09G 2310/0286; G09G 2310/08; G11C 19/28

(57) ABSTRACT

The present disclosure provides a shift register unit, a display panel, a driving method thereof and a display apparatus. The shift register unit comprises an input sub-circuit, a control sub-circuit, a first output sub-circuit and a second output sub-circuit. The input sub-circuit is configured to provide a signal of an input signal end to a third node; the control sub-circuit is configured to control signals of a first node and a second node; the first output sub-circuit is configured to enable a cascade output end to output a cascade signal; and the second output sub-circuit is configured to enable a driving output end to output a gate scanning signal.

### TECHNICAL FIELD

The present disclosure relates to the field of display technology, and in particular, to a shift register unit, a display panel, a driving method thereof, and a display apparatus.

### BACKGROUND

In the current display field, in order to save power consumption of displaying, manufacturers propose a solution of partition frequency conversion, that is, a display panel is divided into a plurality of partitions, and different refresh rates may be set for respective partitions. The partition frequency conversion can realize refreshed areas being updated, and unrefreshed areas being retained to data of previous frames, which further saves the power consumption of displaying.

Design of a partition refresh driving (gate on array, GOA) circuit is the key for realizing the partition refresh.

### SUMMARY

A purpose of the present disclosure is to provide a shift register unit, a display panel, a driving method thereof, and a display apparatus capable of realizing partition refresh.

The present disclosure provides a shift register unit, including:
an input sub-circuit, connected to a third node, an input signal end, a first clock signal end and a third clock signal end, and configured to provide a signal of the input signal end to the third node in response to signals from the first clock signal end and the third clock signal end;
a control sub-circuit, connected to the third node, a first node, a second node, a first power signal end, a second power signal end, the first clock signal end, a second clock signal end and the third clock signal end, and configured to control signals of the first node and the second node and provide a signal of the third node to the first node or the second node in response to signals from the first power signal end, the second power signal end, the first clock signal end, the second clock signal end and the third clock signal end;
a first output sub-circuit, connected to the first node, the second node, the third clock signal end, the first power signal end and a cascade output end, and configured to enable the cascade output end to output a cascade signal in response to signals from the first node and the second node; and
a second output sub-circuit, connected to the first node, the second node, a control signal end, the first power signal end and a driving output end, and configured to enable the driving output end to output a gate scanning signal in response to signals from the first node and the second node.

In some embodiments, the second output sub-circuit includes:
a first output module, connected to the control signal end, the first node and the driving output end, and configured to transmit a signal of the control signal end to the driving output end under control of the first node; and
a second output module, connected to the first power signal end, the second node and the driving output end, and configured to transmit a signal of the first power signal end to the driving output end under control of the second node.

In some embodiments, the first output module includes a fourteenth transistor, a first electrode of the fourteenth transistor is connected to the control signal end, a second electrode of the fourteenth transistor is connected to the driving output end, and a control electrode of the fourteenth transistor is connected to the second node.

In some embodiments, the second output module includes a fifteenth transistor, a first electrode of the fifteenth transistor is connected to the first power signal end, a second electrode of the fifteenth transistor is connected to the driving output end, and a control electrode of the fifteenth transistor is connected to the second node.

In some embodiments, the first output sub-circuit includes:
a fourth transistor, where a first electrode of the fourth transistor is connected to the third clock signal end, a second electrode of the fourth transistor is connected to the cascade output end, and a control electrode of the fourth transistor is connected to the first node; and
a fifth transistor, where a first electrode of the fifth transistor is connected to the first power signal end, a second electrode of the fifth transistor is connected to the cascade output end, and a control electrode of the fifth transistor is connected to the second node.

In some embodiments, the first output sub-circuit further includes a third capacitor, where a first end of the third capacitor is connected to the first electrode of the fourth transistor, and a second end of the third capacitor is connected to the control electrode of the fourth transistor; and/or
where the first output sub-circuit further includes a fourth capacitor, where a first end of the fourth capacitor is connected to the cascade output end, and a second end of the fourth capacitor is connected to the first power signal end.

In some embodiments, the input sub-circuit includes a thirteenth transistor and a second transistor, where
a first electrode of the thirteenth transistor is connected to the input signal end, a second electrode of the thirteenth transistor is connected to a first electrode of the second transistor, and a control electrode of the thirteenth transistor is connected to the third clock signal end;
a second electrode of the second transistor is connected to the third node, and a control electrode of the second transistor is connected to the first clock signal end.

In some embodiments, the control sub-circuit includes a first control sub-module, a first voltage stabilizing module, and a second voltage stabilizing module, where
the first control sub-module is connected to the third node, a fourth node, a fifth node, the first power signal end, the second power signal end, the first clock signal end, the second clock signal end and the third clock signal end, and is configured to control signals of the fourth node and the fifth node and provide the signal of the third node to the fourth node or the fifth node in response to signals from the first power signal end, the second power signal end, the first clock signal end, the second clock signal end and the third clock signal end;
the first voltage stabilizing module is connected to the fourth node, the first node and the first power signal end, and is configured to provide a voltage of the fourth node to the first node in response to a signal from the first power signal end;
the second voltage stabilizing module is connected to the fifth node, the second node and the first power signal end, and is configured to provide a voltage of the fifth node to the second node in response to a signal from the first power signal end.

In some embodiments, the first control sub-module includes a first transistor, a sixth transistor, an eighth transistor, a ninth transistor, a tenth transistor, a third transistor, a seventh transistor, an eleventh transistor, a twelfth transistor, a first capacitor and a second capacitor; where,
a first electrode of the first transistor is connected to the first clock signal end, a second electrode of the first transistor is connected to a sixth node, and a control electrode of the first transistor is connected to the third node;
a first electrode of the sixth transistor is connected to the first power signal end, a second electrode of the sixth transistor is connected to the sixth node, and a control electrode of the sixth transistor is connected to the first clock signal end;
a first electrode of the eighth transistor is connected to the sixth node, a second electrode of the eighth transistor is connected to a control electrode of the ninth transistor, and a control electrode of the eighth transistor is connected to the first power signal end;
a first electrode of the ninth transistor is connected to the second clock signal end, and a second electrode of the ninth transistor is connected to a first electrode of the tenth transistor;
a second electrode of the tenth transistor is connected to the fourth node, and a control electrode of the tenth transistor is connected to the second clock signal end;
a first electrode of the third transistor is connected to the second clock signal end, a second electrode of the third transistor is connected to a second electrode of the seventh transistor, and a control electrode of the third transistor is connected to the fifth node;
a first electrode of the seventh transistor is connected to the second power signal end, and a control electrode of the seventh transistor is connected to the sixth node;
a first electrode of the eleventh transistor is connected to the third node, a second electrode of the eleventh transistor is connected to the fifth node, and a control electrode of the eleventh transistor is connected to the first power signal end;
a first electrode of the twelfth transistor is connected to the third clock signal end, a second electrode of the twelfth transistor is connected to the fourth node, and a control electrode of the twelfth transistor is connected to the fifth node;
a first electrode of the first capacitor is connected to the fifth node, and a second electrode of the first capacitor is connected to the second electrode of the third transistor;
a first electrode of the second capacitor is connected to the control electrode of the ninth transistor, and a second electrode of the second capacitor is connected to the second electrode of the ninth transistor;
the first voltage stabilizing module includes a sixteenth transistor, where a first electrode of the sixteenth transistor is connected to the fourth node, a second electrode of the sixteenth transistor is connected to the first node, and a control electrode of the sixteenth transistor is connected to the first power signal end;
the second voltage stabilizing module includes a seventeenth transistor, where a first electrode of the seventeenth transistor is connected to the fifth node, and a second electrode of the seventeenth transistor is connected to the first node.

In some embodiments, the control sub-circuit includes a second control sub-module, a third voltage stabilizing module, and a fourth voltage stabilizing module, where
the second control sub-module is connected to the third node, a fourth node, the first node, the first power signal end, the second power signal end, the first clock signal end, the second clock signal end and the third clock signal end, and is configured to control a signal of the fourth node and provide the signal of the third node to the fourth node in response to signals from the first power signal end, the second power signal end, the first clock signal end, the second clock signal end and the third clock signal end;
the third voltage stabilizing module is connected to the fourth node, the first node and the first power signal end, and is configured to provide a voltage of the fourth node to the first node in response to a signal from the first power signal end;
the fourth voltage stabilizing module is connected to the third node, the second node and the first power signal end, and is configured to provide a voltage of the third node to the second node in response to the signal from the first power signal end.

In some embodiments, the second control sub-module includes a first transistor, a sixth transistor, an eighth transistor, a ninth transistor, a tenth transistor, a third transistor, a seventh transistor, a twelfth transistor, a first capacitor and a second capacitor; where,
a first electrode of the first transistor is connected to the first clock signal end, a second electrode of the first transistor is connected to a sixth node, and a control electrode of the first transistor is connected to the third node;
a first electrode of the sixth transistor is connected to the first power signal end, a second electrode of the sixth transistor is connected to the sixth node, and a control electrode of the sixth transistor is connected to the first clock signal end;
a first electrode of the eighth transistor is connected to the sixth node, a second electrode of the eighth transistor is connected to a control electrode of the ninth transistor, and a control electrode of the eighth transistor is connected to the first power signal end;
a first electrode of the ninth transistor is connected to the second clock signal end, and a second electrode of the ninth transistor is connected to a first electrode of the tenth transistor;
a second electrode of the tenth transistor is connected to the fourth node, and a control electrode of the tenth transistor is connected to the second clock signal end;
a first electrode of the third transistor is connected to the second clock signal end, a second electrode of the third transistor is connected to a second electrode of the seventh transistor, and a control electrode of the third transistor is connected to the third node;
a first electrode of the seventh transistor is connected to the second power signal end, and a control electrode of the seventh transistor is connected to the sixth node;
a first electrode of the twelfth transistor is connected to the third clock signal end, a second electrode of the twelfth transistor is connected to the fourth node, and a control electrode of the twelfth transistor is connected to the third node;
a first electrode of the first capacitor is connected to the third node, and a second electrode of the first capacitor is connected to the second electrode of the third transistor;
a first electrode of the second capacitor is connected to the control electrode of the ninth transistor, and a second electrode of the second capacitor is connected to the second electrode of the ninth transistor;
the third voltage stabilizing module includes a sixteenth transistor, where a first electrode of the sixteenth transistor is connected to the fourth node, a second electrode of the sixteenth transistor is connected to the first node, and a control electrode of the sixteenth transistor is connected to the first power signal end;
the fourth voltage stabilizing module includes an eleventh transistor, a first electrode of the eleventh transistor is connected to the third node, and a second electrode of the eleventh transistor is connected to the first node.

In some embodiments, the control sub-circuit includes a third control sub-module and a fifth voltage stabilizing module, where
the third control sub-module is connected to the third node, the first node, the first power signal end, the second power signal end, the first clock signal end, the second clock signal end and the third clock signal end, and is configured to control a signal of the first node and provide the signal of the third node to the first node in response to signals from the first power signal end, the second power signal end, the first clock signal end, the second clock signal end and the third clock signal end;
the fifth voltage stabilizing module is connected to the third node, the second node and the first power signal end, and is configured to provide a voltage of the third node to the second node in response to the signal from the first power signal end.

In some embodiments, the third control sub-module includes a first transistor, a sixth transistor, an eighth transistor, a ninth transistor, a tenth transistor, a third transistor, a seventh transistor, a twelfth transistor, a first capacitor and a second capacitor; where,
a first electrode of the first transistor is connected to the first clock signal end, a second electrode of the first transistor is connected to a sixth node, and a control electrode of the first transistor is connected to the third node;
a first electrode of the sixth transistor is connected to the first power signal end, a second electrode of the sixth transistor is connected to the sixth node, and a control electrode of the sixth transistor is connected to the first clock signal end;
a first electrode of the eighth transistor is connected to the sixth node, a second electrode of the eighth transistor is connected to a control electrode of the ninth transistor, and a control electrode of the eighth transistor is connected to the first power signal end;
a first electrode of the ninth transistor is connected to the second clock signal end, and a second electrode of the ninth transistor is connected to a first electrode of the tenth transistor;
a second electrode of the tenth transistor is connected to the first node, and a control electrode of the tenth transistor is connected to the second clock signal end;
a first electrode of the third transistor is connected to the second clock signal end, a second electrode of the third transistor is connected to a second electrode of the seventh transistor, and a control electrode of the third transistor is connected to the third node;
a first electrode of the seventh transistor is connected to the second power signal end, and a control electrode of the seventh transistor is connected to the sixth node;
a first electrode of the twelfth transistor is connected to the third clock signal end, a second electrode of the twelfth transistor is connected to the first node, and a control electrode of the twelfth transistor is connected to the third node;
a first electrode of the first capacitor is connected to the third node, and a second electrode of the first capacitor is connected to the second electrode of the third transistor;
a first electrode of the second capacitor is connected to the control electrode of the ninth transistor, and a second electrode of the second capacitor is connected to the second electrode of the ninth transistor;
the fifth voltage stabilizing module includes an eleventh transistor, a first electrode of the eleventh transistor is connected to the third node, and a second electrode of the eleventh transistor is connected to the first node.

In some embodiments, the control sub-circuit includes a fourth control sub-module and a sixth voltage stabilizing module, where
where the fourth control sub-module is connected to the third node, the first node, a fifth node, the first power signal end, the second power signal end, the first clock signal end, the second clock signal end and the third clock signal end, and is configured to control signals of the first node and the fifth node and provide the signal of the third node to the first node or the fifth node in response to signals from the first power signal end, the second power signal end, the first clock signal end, the second clock signal end and the third clock signal end;
the sixth voltage stabilizing module is connected to the fifth node, the second node and the first power signal end, and is configured to provide a voltage of the fifth node to the second node in response to the signal from the first power signal end.

In some embodiments, the fourth control sub-module includes a first transistor, a sixth transistor, an eighth transistor, a ninth transistor, a tenth transistor, a third transistor, a seventh transistor, an eleventh transistor, a twelfth transistor, a first capacitor and a second capacitor; where,
a first electrode of the first transistor is connected to the first clock signal end, a second electrode of the first transistor is connected to a sixth node, and a control electrode of the first transistor is connected to the third node;
a first electrode of the sixth transistor is connected to the first power signal end, a second electrode of the sixth transistor is connected to the sixth node, and a control electrode of the sixth transistor is connected to the first clock signal end;
a first electrode of the eighth transistor is connected to the sixth node, a second electrode of the eighth transistor is connected to a control electrode of the ninth transistor, and a control electrode of the eighth transistor is connected to the first power signal end;
a first electrode of the ninth transistor is connected to the second clock signal end, and a second electrode of the ninth transistor is connected to a first electrode of the tenth transistor;
a second electrode of the tenth transistor is connected to the first node, and a control electrode of the tenth transistor is connected to the second clock signal end;
a first electrode of the third transistor is connected to the second clock signal end, a second electrode of the third transistor is connected to a second electrode of the seventh transistor, and a control electrode of the third transistor is connected to the fifth node;
a first electrode of the seventh transistor is connected to the second power signal end, and a control electrode of the seventh transistor is connected to the sixth node;
a first electrode of the eleventh transistor is connected to the third node, a second electrode of the eleventh transistor is connected to the fifth node, and a control electrode of the eleventh transistor is connected to the first power signal end;
a first electrode of the twelfth transistor is connected to the third clock signal end, a second electrode of the twelfth transistor is connected to the first node, and a control electrode of the twelfth transistor is connected to the fifth node;
a first electrode of the first capacitor is connected to the fifth node, and a second electrode of the first capacitor is connected to the second electrode of the third transistor;
a first electrode of the second capacitor is connected to the control electrode of the ninth transistor, and a second electrode of the second capacitor is connected to the second electrode of the ninth transistor;
the sixth voltage stabilizing module includes a seventeenth transistor, where a first electrode of the seventeenth transistor is connected to the fifth node, and a second electrode of the seventeenth transistor is connected to the first node.

In some embodiments, the control sub-circuit includes a fifth control sub-module and a seventh voltage stabilizing module; where
the fifth control sub-module is connected to the third node, a fourth node, the second node, the first power signal end, the second power signal end, the first clock signal end, the second clock signal end and the third clock signal end, and is configured to control signals of the fourth node and the second node and provide the signal of the third node to the fourth node or the second node in response to signals from the first power signal end, the second power signal end, the first clock signal end, the second clock signal end and the third clock signal end;
the seventh voltage stabilizing module is connected to the fourth node, the first node and the first power signal end, and is configured to provide a voltage of the fourth node to the first node in response to a signal from the first power signal end.

In some embodiments, the fifth control sub-module includes a first transistor, a sixth transistor, an eighth transistor, a ninth transistor, a tenth transistor, a third transistor, a seventh transistor, an eleventh transistor, a twelfth transistor, a first capacitor and a second capacitor; where,
a first electrode of the first transistor is connected to the first clock signal end, a second electrode of the first transistor is connected to a sixth node, and a control electrode of the first transistor is connected to the third node;
a first electrode of the sixth transistor is connected to the first power signal end, a second electrode of the sixth transistor is connected to the sixth node, and a control electrode of the sixth transistor is connected to the first clock signal end;
a first electrode of the eighth transistor is connected to the sixth node, a second electrode of the eighth transistor is connected to a control electrode of the ninth transistor, and a control electrode of the eighth transistor is connected to the first power signal end;
a first electrode of the ninth transistor is connected to the second clock signal end, and a second electrode of the ninth transistor is connected to a first electrode of the tenth transistor;
a second electrode of the tenth transistor is connected to the fourth node, and a control electrode of the tenth transistor is connected to the second clock signal end;
a first electrode of the third transistor is connected to the second clock signal end, a second electrode of the third transistor is connected to a second electrode of the seventh transistor, and a control electrode of the third transistor is connected to the second node;
a first electrode of the seventh transistor is connected to the second power signal end, and a control electrode of the seventh transistor is connected to the sixth node;
a first electrode of the eleventh transistor is connected to the third node, a second electrode of the eleventh transistor is connected to the second node, and a control electrode of the eleventh transistor is connected to the first power signal end;
a first electrode of the first transistor is connected to the first clock signal end, a second electrode of the first transistor is connected to a sixth node, and a control electrode of the first transistor is connected to the third node;
a first electrode of the first capacitor is connected to the second node, and a second electrode of the first capacitor is connected to the second electrode of the third transistor;
a first electrode of the second capacitor is connected to the control electrode of the ninth transistor, and a second electrode of the second capacitor is connected to the second electrode of the ninth transistor;
the seventh voltage stabilizing module includes a sixteenth transistor, where a first electrode of the sixteenth transistor is connected to the fourth node, a second electrode of the sixteenth transistor is connected to the first node, and a control electrode of the sixteenth transistor is connected to the first power signal end.

The present disclosure further discloses a display panel, including:
a substrate, including a display area and a non-display area;
the display area includes:
sub-pixels;
scanning lines, where one row of the sub-pixels is coupled to at least one of the scanning lines;
where the non-display area includes:
a gate driving circuit, including shift register units described above, where the driving output end of each of the shift register units is connected to at least one of the scanning lines;
for two adjacent shift register units, the input signal end of a latter one of the shift register units is coupled to the cascade output end of a former one of the shift register units.

In some embodiments, the display panel further includes control signal lines coupled to the gate driving circuit, where an extending direction of each of the control signal lines is same as an arrangement direction of the shift register units.

In some embodiments, an orthographic projection of the control signal lines on the substrate is located between an orthographic projection of the gate driving circuit on the substrate and the display area.

In some embodiments, the control signal lines include a first control sub-signal line and a second control sub-signal line; and the first control sub-signal line is coupled to the control signal ends of odd-numbered shift register units, and the second control sub-signal line is coupled to the control signal ends of even-numbered shift register units.

In some embodiments, the display panel further includes auxiliary control signal lines, where an insulating layer is disposed between the auxiliary control signal lines and the control signal lines;
the auxiliary control signal lines are in one-to-one correspondence with the control signal lines, and the auxiliary control signal line and the corresponding control signal line are coupled to each other by holes penetrating through the insulating layer.

In some embodiments, the display panel further includes clock signal lines, where an extending direction of each of the clock signal lines is same as the arrangement direction of the shift register units.

In some embodiments, the orthographic projection of the gate driving circuit on the substrate is located between an orthographic projection of the clock signal lines on the substrate and the orthographic projection of the control signal lines on the substrate.

In some embodiments, the display panel includes a first clock signal line, a second clock signal line, a third clock signal line and a fourth clock signal line; where
the first clock signal ends of odd-numbered shift register units and the second clock signal ends of even-numbered shift register units are coupled to the first clock signal line;
the second clock signal ends of the odd-numbered shift register units and the first clock signal ends of the even-numbered shift register units are coupled to the second clock signal line;
the third clock signal ends of the odd-numbered shift register units are coupled to the fourth clock signal line;
the third clock signal ends of the even-numbered shift register units are coupled to the third clock signal line.

In some embodiments, when the first output sub-circuit includes a fourth capacitor, an orthographic projection of the fourth capacitor C4 on the substrate is located on a side of the shift register unit, where the fourth capacitor is currently located, close to a next shift register unit.

In some embodiments, the fourth capacitor C4 is less than 120 farads.

In some embodiments, when the first output sub-circuit includes a fourth transistor and the second output sub-circuit includes a fourteenth transistor, an orthographic projection of the fourteenth transistor on the substrate is located between an orthographic projection of the fourth transistor on the substrate and the display area; and when the first output sub-circuit includes a fifth transistor and the second output sub-circuit includes a fifteenth transistor, an orthographic projection of the fifteenth transistor on the substrate is located between an orthographic projection of the fifth transistor on the substrate and the display area.

In some embodiments, a channel width of the fourteenth transistor is greater than a channel width of the fourth transistor.

In some embodiments, the channel width of the fourteenth transistor is not less than 100 μm.

In some embodiments, the channel width of the fourth transistor is not greater than 60 μm.

In some embodiments, a channel width of the fifteenth transistor is greater than a channel width of the fifth transistor.

In some embodiments, the channel width of the fifteenth transistor is not less than 100 μm.

In some embodiments, the channel width of the fifth transistor is not greater than 60 μm.

The present disclosure further discloses a display apparatus, including:
the display panel as described above;
a driving control circuit, coupled to the display panel, and configured to input a first signal to the control signal ends of the shift register units when a full-screen refresh mode is determined to be adopted, so that the shift register units sequentially output gate scanning signals and drive the scanning lines row by row;
the driving control circuit is configured to input a second signal to the control signal ends of the shift register units when a partition refresh mode is determined to be adopted, so that part of the shift register units sequentially output gate scanning signals, and rest of the shift register units output invalid scanning signals.

The present disclosure further discloses a driving method for driving the above display panel, including:
outputting a first signal to the control signal ends of the shift register units when a full-area refresh mode is determined to be adopted, so that the shift register units sequentially output gate scanning signals and drive the scanning lines row by row;
outputting a second signal to the control signal ends of the shift register units when a partition refresh mode is determined to be adopted, so that part of the shift register units sequentially output gate scanning signals, and rest of the shift register units output invalid scanning signals to drive part of the scanning lines.

In some embodiments, the first signal is a clock signal.

In some embodiments, the second signal includes a fixed signal portion including a clock signal and a fixed signal portion including a second electrical level, the fixed signal portion including the clock signal is input into part of the shift register units, and the fixed signal portion including the second electrical level is input into rest of the shift register units.

Compared with related arts, the second output sub-circuit of the present disclosure is connected to the control signal end and the driving output end, the control signal end is connected to the driving output end under control of the first node, and the control signal end is connected to one of the control signal lines. The driving output end may output a gate scanning signal for controlling the partition refresh.

It should be understood that the above general description and the following detailed description are merely illustrative and explanatory, and do not limit the present specification.

### BRIEF DESCRIPTION OF DRAWINGS

The accompanying drawings, which are incorporated in and constitute a part of this specification, illustrate embodiments consistent with this specification and together with the description serve to explain the principles of this specification.

FIG. 1 is a schematic structural diagram of a shift register unit according to an embodiment of the present disclosure.

FIG. 2 is a circuit diagram of a shift register unit according to an embodiment of the present disclosure.

FIG. 3 is a schematic structural diagram of a display panel according to an embodiment of the present disclosure.

FIG. 4 is a schematic structural diagram of a display apparatus according to an embodiment of the present disclosure.

FIG. 5 is a flowchart of a driving method according to an embodiment of the present disclosure.

FIG. 6 is a signal timing diagram according to an embodiment of the present disclosure.

FIG. 7 is another signal timing diagram according to an embodiment of the present disclosure.

FIG. 8 is a schematic partial layout structural diagram of a shift register unit according to an embodiment of the present disclosure.

FIG. 9 is a schematic partially enlarged diagram of the shift register unit shown in FIG. 8.

FIG. 10 is another schematic partially enlarged diagram of the shift register unit shown in FIG. 8.

FIG. 11 to FIG. 16 are schematic structural diagrams of respective layers of the partial layout of the shift register unit shown in FIG. 9.

FIG. 17 is a circuit diagram of another shift register unit according to an embodiment of the present disclosure.

FIG. 18 is a circuit diagram of another shift register unit according to an embodiment of the present disclosure.

FIG. 19 is a circuit diagram of another shift register unit according to an embodiment of the present disclosure.

FIG. 20 is a circuit diagram of another shift register unit according to an embodiment of the present disclosure.

### DETAILED DESCRIPTION

Exemplary embodiments will be described in detail herein, examples of which are illustrated in the accompanying drawings. When following description refers to the drawings, unless otherwise indicated, same numerals in different drawings indicate same or similar elements. Implementations described in the following exemplary embodiments do not represent all implementations consistent with this specification. Rather, they are merely examples of apparatuses and methods consistent with some aspects of the specification as detailed in the appended claims.

Terms used herein are for the purpose of describing particular embodiments only, and are not intended to limit the present disclosure. Unless otherwise defined, technical terms or scientific terms used in this specification should be general meanings understood by those skilled in the art to which the present disclosure belongs. As used in this specification and claims, “first”, “second” and similar words do not represent any order, quantity, or importance, but are merely used to distinguish different components. Similarly, words such as “a” or “an” do not indicate a quantity limitation, but indicate that there is one or more. “Multiple” or “several” means two or more. Unless otherwise indicated, words such as “front,” “rear,” “lower,” and/or “upper” are for ease of illustration only and are not limited to one position or one spatial orientation. Words such as “include” or “comprise” mean that elements or objects appearing before “include” or “comprise” cover elements or objects listed after “include” or “comprise” and equivalents thereof, and do not exclude other elements or objects. Terms “connected” or “coupled” and the like are not limited to physical or mechanical connections, and may include electrical connections, whether direct or indirect.

The terms used in this specification are for the purpose of describing particular embodiments only and are not intended to limit the present disclosure. As used in this specification and the appended claims, singular forms “a”, “the”, and “said” are also intended to include plural forms unless the context clearly indicates other meanings. It should also be understood that the term “and/or” as used herein refers to and encompasses any or all possible combinations of one or more associated listed items.

The transistor used in the present disclosure may be a triode, a thin film transistor or a field effect transistor or other devices with same characteristics. In the embodiments of the present disclosure, in order to distinguish two electrodes except for the control electrode of the transistor, one of the electrodes is referred to as a first electrode, and another one of the electrodes is referred to as a second electrode. An energy storage unit used in the present disclosure may be a capacitor.

In practice, when the transistor is a triode, the control electrode may be a base electrode, the first electrode may be a collector electrode, and the second electrode may be an emitter electrode; alternatively, the control electrode may be a base electrode, the first electrode may be an emitter electrode, and the second electrode may be a collector electrode.

In practice, when the transistor is a thin film transistor or a field effect transistor, the control electrode may be a gate electrode, the first electrode may be a drain electrode, and the second electrode may be a source electrode; alternatively, the control electrode may be a gate electrode, the first electrode may be a source electrode, and the second electrode may be a drain electrode.

Illustratively, in order to reduce the manufacturing process, all transistors may be provided as P-type transistors; alternatively, all transistors may be provided as N-type transistors, which is not limited herein. Further, the N-type transistor is turned on under the action of a high-level signal and is turned off under the action of a low-level signal; and the P-type transistor is turned off under the action of a high-level signal and is turned on under the action of a low-level signal. In the present disclosure, all transistors being P-type transistors is used as an example for description.

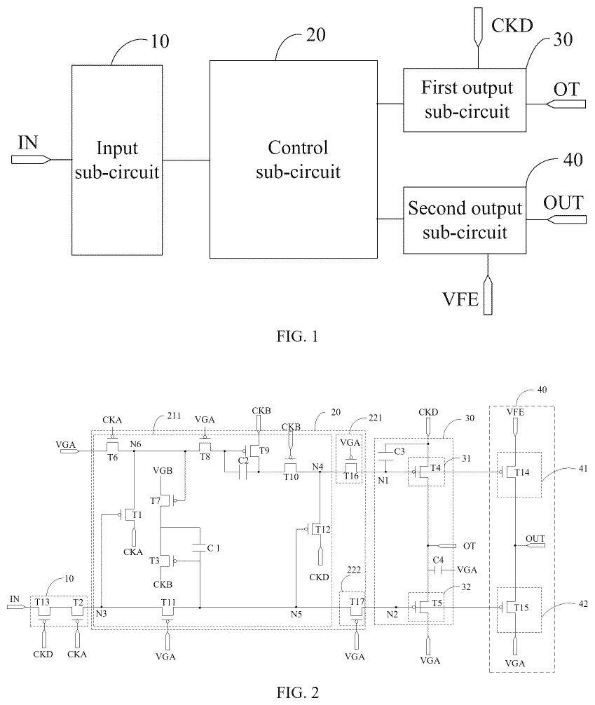

An embodiment of the present disclosure provides a shift register unit, as shown in FIG. 1 and FIG. 2, including an input sub-circuit 10, a control sub-circuit 20, a first output sub-circuit 30 and a second output sub-circuit 40.

The input sub-circuit 10 is connected to a third node N3, an input signal end IN, a first clock signal end CKA and a third clock signal end CKD, and configured to provide a signal of the input signal end IN to the third node N3 in response to signals from the first clock signal end CKA and the third clock signal end CKD.

The control sub-circuit 20 is connected to the third node N3, a first node N1, a second node N2, a first power signal end VGA, a second power signal end VGB, the first clock signal end CKA, a second clock signal end CKB and the third clock signal end CKD, and configured to control signals of the first node N1 and the second node N2 and provide a signal of the third node N3 to the first node N1 or the second node N2 in response to signals from the first power signal end VGA, the second power signal end VGB, the first clock signal end CKA, the second clock signal end CKB and the third clock signal end CKD.

The first output sub-circuit 130 is connected to the first node N1, the second node N2, the third clock signal end CKD, the first power signal end VGA and a cascade output end OT, and configured to enable the cascade output end OT to output a cascade signal in response to signals from the first node N1 and the second node N2.

The second output sub-circuit 40 is connected to the first node N1, the second node N2, a control signal end VFE, the first power signal end VGA and a driving output end OUT, and configured to enable the driving output end OUT to output a gate scanning signal in response to signals from the first node N1 and the second node N2.

The shift register unit provided by the embodiment of the present disclosure controls a gate scanning signal of a driving output end OUT by controlling a signal of the control signal end VFE. When the shift register unit is applied to a display panel, scanning of any region of the display panel can be controlled by controlling the signal of the control signal end VFE, thereby realizing flexible adjustment of refresh frequencies in different regions, saving power consumption and reducing losses.

As shown in FIG. 1 and FIG. 2, in some embodiments of the present disclosure, the input sub-circuit 10 includes a thirteenth transistor T13 and a second transistor T2.

A first electrode of the thirteenth transistor T13 is connected to the input signal end IN, a second electrode of the thirteenth transistor T13 is connected to a first electrode of the second transistor T2, and a control electrode of the thirteenth transistor T13 is connected to the third clock signal end CKD.

A second electrode of the second transistor T2 is connected to the third node N3, and a control electrode of the second transistor T2 is connected to the first clock signal end CKA.

In some embodiments, the control sub-circuit 20 includes a first control sub-module 211, a first voltage stabilizing module 221, and a second voltage stabilizing module 222 to stabilize voltages of the first node N1 and the second node N2, respectively.

The first control sub-module 211 is connected to the third node N3, a fourth node N4, a fifth node N5, the first power signal end VGA, the second power signal end VGB, the first clock signal end CKA, the second clock signal end CKB and the third clock signal end CKD, and is configured to control signals of the fourth node N4 and the fifth node N5 and provide the signal of the third node N3 to the fourth node N4 or the fifth node N5 in response to signals from the first power signal end VGA, the second power signal end VGB, the first clock signal end CKA, the second clock signal end CKB and the third clock signal end CKD.

The first voltage stabilizing module 221 is connected to the fourth node N4, the first node N1 and the first power signal end VGA, and is configured to provide a voltage of the fourth node N4 to the first node N1 in response to a signal from the first power signal end VGA.

The second voltage stabilizing module 222 is connected to the fifth node N5, the second node N2 and the first power signal end VGA, and is configured to provide a voltage of the fifth node N5 to the second node N2 in response to a signal from the first power signal end VGA.

Specifically, still referring to FIG. 2, in some embodiments, the first control sub-module 211 includes a first transistor T1, a sixth transistor T6, an eighth transistor T8, a ninth transistor T9, a tenth transistor T10, a third transistor T3, a seventh transistor T7, an eleventh transistor T11, a twelfth transistor T12, a first capacitor C1 and a second capacitor C2.

A first electrode of the first transistor T1 is connected to the first clock signal end CKA, a second electrode of the first transistor T1 is connected to a sixth node N6, and a control electrode of the first transistor T1 is connected to the third node N3.

A first electrode of the sixth transistor T6 is connected to the first power signal end VGA, a second electrode of the sixth transistor T6 is connected to the sixth node N6, and a control electrode of the sixth transistor T6 is connected to the first clock signal end CKA.

A first electrode of the eighth transistor T8 is connected to the sixth node N6, a second electrode of the eighth transistor T8 is connected to a control electrode of the ninth transistor T9, and a control electrode of the eighth transistor T8 is connected to the first power signal end VGA.

A first electrode of the ninth transistor T9 is connected to the second clock signal end CKB, and a second electrode of the ninth transistor T9 is connected to a first electrode of the tenth transistor T10.

A second electrode of the tenth transistor T10 is connected to the fourth node N4, and a control electrode of the tenth transistor T10 is connected to the second clock signal end CKB.

A first electrode of the third transistor T3 is connected to the second clock signal end CKB, a second electrode of the third transistor T3 is connected to a second electrode of the seventh transistor T7, and a control electrode of the third transistor T3 is connected to the fifth node N5.

A first electrode of the seventh transistor T7 is connected to the second power signal end VGB, and a control electrode of the seventh transistor T7 is connected to the sixth node N6.

A first electrode of the eleventh transistor T11 is connected to the third node N3, a second electrode of the eleventh transistor T11 is connected to the fifth node N5, and a control electrode of the eleventh transistor T11 is connected to the first power signal end CKA.

A first electrode of the twelfth transistor T12 is connected to the third clock signal end CKD, a second electrode of the twelfth transistor T12 is connected to the fourth node N4, and a control electrode of the twelfth transistor T12 is connected to the fifth node N5.

A first electrode of the first capacitor C1 is connected to the fifth node N5, and a second electrode of the first capacitor C1 is connected to a second electrode of the third transistor T3.

A first electrode of the second capacitor C2 is connected to the control electrode of the ninth transistor T9, and a second electrode of the second capacitor C2 is connected to the second electrode of the ninth transistor T9.

The first voltage stabilizing module 221 includes a sixteenth transistor T16, a first electrode of the sixteenth transistor T16 is connected to the fourth node N4, a second electrode of the sixteenth transistor T16 is connected to the first node N1, and a control electrode of the sixteenth transistor T16 is connected to the first power signal end VGA; and the sixteenth transistor T16 is provided to prevent current backflow and improve circuit stability.

The second voltage stabilizing module 222 includes a seventeenth transistor T17, a first electrode of the seventeenth transistor T17 is connected to the fifth node N5, and a second electrode of the seventeenth transistor T17 is connected to the first node N1. The seventeenth transistor T17 can prevent current backflow and improve the stability of the circuit.

It can be understood that the first voltage stabilizing module and the second voltage stabilizing module may also be configured as other voltage stabilizing circuit structures. The first capacitor C1 and the second capacitor C2 may be capacitors with a capacity of 20 farads to 30 farads (i.e., 20 f-30 f). For example, the first capacitor C1 is a capacitor of 30 f, and the second capacitor C2 is a capacitor of 20 f.

Still referring to FIG. 2, in some embodiments, the first output sub-circuit 30 includes a fourth transistor T4 and a fifth transistor T5.

A first electrode of the fourth transistor T4 is connected to the third clock signal end CKD, a second electrode of the fourth transistor T4 is connected to the cascade output end OT, and a control electrode of the fourth transistor T4 is connected to the first node N1.

A first electrode of the fifth transistor T5 is connected to the first power signal end VGA, a second electrode of the fifth transistor T5 is connected to the cascade output end OT, and a control electrode of the fifth transistor T5 is connected to the second node N2.

In some embodiments, the first output sub-circuit 30 further includes a third capacitor C3, a first end of the third capacitor C3 is connected to the first electrode of the fourth transistor T4, and a second end of the third capacitor C3 is connected to the control electrode of the fourth transistor T4. Optionally, the third capacitor is a capacitor of 50 f.

Considering that there is no load on a signal line of the first output sub-circuit 30, it tends to cause instability of cascade signals. Based on this, a capacitor with a large capacity is coupled to the cascade output end OT.

For example, as shown in FIG. 2, in some embodiments, the first output sub-circuit 30 further includes a fourth capacitor C4, a first end of the fourth capacitor C4 is connected to the cascade output end OT, and a second end of the fourth capacitor C4 is connected to the first power signal end VGA.

In some embodiments, the fourth capacitor C4 is less than 120 farads (i.e., 120 f). A large capacitor but less than 120 farads may be provided. Optionally, the fourth capacitor C4 is a capacitor of 100 f. The fourth capacitor C4 may make the cascade signal output by the first output sub-circuit 30 more stable.

It should be noted that, in some other embodiments, the first output sub-circuit 30 may not include the third capacitor and the fourth capacitor, or include only one of the third capacitor and the fourth capacitor.

In some embodiments, the second output sub-circuit 40 includes:
a first output module 41, connected to the control signal end VFE, the first node N1 and the driving output end OUT, and configured to transmit a signal of the control signal end VFE to the driving output end OUT under control of the first node N1; and
a second output module 42, connected to the first power signal end VGA, the second node N2 and the driving output end OUT, and configured to transmit a signal of the first power signal end VGA to the driving output end OUT under control of the second node N2.

In some embodiments, the first output module 41 includes a fourteenth transistor T14, a first electrode of the fourteenth transistor T14 is connected to the control signal end VFE, a second electrode of the fourteenth transistor T14 is connected to the driving output end OUT, and a control electrode of the fourteenth transistor T14 is connected to the second node N2.

In some embodiments, the second output module 42 includes a fifteenth transistor T15, a first electrode of the fifteenth transistor T15 is connected to the first power signal end VGA, a second electrode of the fifteenth transistor T15 is connected to the driving output end OUT, and a control electrode of the fifteenth transistor T15 is connected to the second node N2.

Referring to FIG. 1 and FIG. 17, in another embodiment of the present disclosure, the control sub-circuit 20 includes a second control sub-module 212, a third voltage stabilizing module 223, and a fourth voltage stabilizing module 224.

The second control sub-module 212 is connected to the third node N3, the fourth node N4, the first node N1, the first power signal end VGA, the second power signal end VGB, the first clock signal end CKA, the second clock signal end CKB and the third clock signal end CKD, and is configured to control a signal of the fourth node N4 and provide the signal of the third node N3 to the fourth node N4 in response to signals from the first power signal end VGA, the second power signal end VGB, the first clock signal end CKA, the second clock signal end CKB and the third clock signal end CKD.

The third voltage stabilizing module 223 is connected to the fourth node N4, the first node N1 and the first power signal end VGA, and is configured to provide a voltage of the fourth node N4 to the first node N1 in response to a signal from the first power signal end VGA.

The fourth voltage stabilizing module 224 is connected to the third node N3, the second node N2 and the first power signal end VGA, and is configured to provide a voltage of the third node N3 to the second node N2 in response to the signal from the first power signal end VGA.

Referring to FIG. 17, the second control sub-module 212 includes a first transistor T1, a sixth transistor T6, an eighth transistor T8, a ninth transistor T9, a tenth transistor T10, a third transistor T3, a seventh transistor T6, a twelfth transistor T6, a first capacitor C6 and a second capacitor C6.

A first electrode of the first transistor T1 is connected to the first clock signal end CKA, a second electrode of the first transistor T1 is connected to a sixth node N6, and a control electrode of the first transistor T1 is connected to the third node N3.

A first electrode of the sixth transistor T6 is connected to the first power signal end VGA, a second electrode of the sixth transistor T6 is connected to the sixth node N6, and a control electrode of the sixth transistor T6 is connected to the first clock signal end CKA.

A first electrode of the eighth transistor T8 is connected to the sixth node N6, a second electrode of the eighth transistor T8 is connected to a control electrode of the ninth transistor T9, and a control electrode of the eighth transistor T8 is connected to the first power signal end VGA.

A first electrode of the ninth transistor T9 is connected to the second clock signal end CKB, and a second electrode of the ninth transistor T9 is connected to a first electrode of the tenth transistor T10.

A second electrode of the tenth transistor T10 is connected to the fourth node N4, and a control electrode of the tenth transistor T10 is connected to the second clock signal end CKB.

A first electrode of the third transistor T3 is connected to the second clock signal end CKB, a second electrode of the third transistor T3 is connected to a second electrode of the seventh transistor T7, and a control electrode of the third transistor T3 is connected to the third node N3.

A first electrode of the seventh transistor T7 is connected to the second power signal end VGB, and a control electrode of the seventh transistor T7 is connected to the sixth node N6.

A first electrode of the twelfth transistor T12 is connected to the third clock signal end CKD, a second electrode of the twelfth transistor T12 is connected to the fourth node N4, and a control electrode of the twelfth transistor T12 is connected to the third node N3.

A first electrode of the first capacitor C1 is connected to the third node N3, and a second electrode of the first capacitor C1 is connected to a second electrode of the third transistor T3.

A first electrode of the second capacitor C2 is connected to the control electrode of the ninth transistor T9, and a second electrode of the second capacitor C2 is connected to the second electrode of the ninth transistor T9.

The third voltage stabilizing module 223 includes a sixteenth transistor T16, where a first electrode of the sixteenth transistor T16 is connected to the fourth node N4, a second electrode of the sixteenth transistor is connected to the first node N1, and a control electrode of the sixteenth transistor T16 is connected to the first power signal end VGA.

The fourth voltage stabilizing module 224 includes an eleventh transistor T11, a first electrode of the eleventh transistor T11 is connected to the third node N3, and a second electrode of the eleventh transistor T11 is connected to the first node N1.

It should be noted that, compared with the implementation shown in FIG. 2, in the implementation shown in FIG. 17, T11 is directly moved rightward to form the fourth voltage stabilizing module for stabilizing the voltage of the second node N2. Same or similar parts can be referred from the related description of the embodiments shown in FIG. 2.

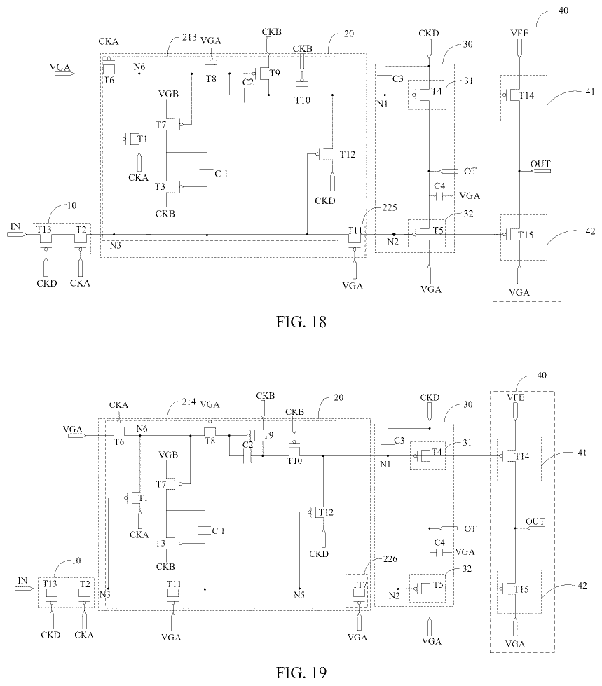

Referring to FIG. 1 and FIG. 18, in another embodiment of the present disclosure, the control sub-circuit 20 includes a third control sub-module 213 and a fifth voltage stabilizing module 225.

The third control sub-module 213 is connected to the third node N3, the first node N1, the first power signal end VGA, the second power signal end VGB, the first clock signal end CKA, the second clock signal end CKB and the third clock signal end CKD, and is configured to control a signal of the first node N1 and provide the signal of the third node N3 to the first node N1 in response to signals from the first power signal end VGA, the second power signal end VGB, the first clock signal end CKA, the second clock signal end CKB and the third clock signal end CKD.

The fifth voltage stabilizing module 225 is connected to the third node N3, the second node N2 and the first power signal end VGA, and is configured to provide a voltage of the third node N3 to the second node N2 in response to the signal from the first power signal end VGA.

Referring to FIG. 18, the third control sub-module 213 includes a first transistor T1, a sixth transistor T6, an eighth transistor T8, a ninth transistor T9, a tenth transistor T10, a third transistor T3, a seventh transistor T6, a twelfth transistor T6, a first capacitor C6 and a second capacitor C6.

A first electrode of the first transistor T1 is connected to the first clock signal end CKA, a second electrode of the first transistor T1 is connected to a sixth node N6, and a control electrode of the first transistor T1 is connected to the third node N3.

A first electrode of the sixth transistor T6 is connected to the first power signal end VGA, a second electrode of the sixth transistor T6 is connected to the sixth node N6, and a control electrode of the sixth transistor T6 is connected to the first clock signal end CKA.

A first electrode of the eighth transistor T8 is connected to the sixth node N6, a second electrode of the eighth transistor T8 is connected to a control electrode of the ninth transistor T9, and a control electrode of the eighth transistor T8 is connected to the first power signal end VGA.

A first electrode of the ninth transistor T9 is connected to the second clock signal end CKB, and a second electrode of the ninth transistor T9 is connected to a first electrode of the tenth transistor T10.

A second electrode of the tenth transistor T10 is connected to the first node N1, and a control electrode of the tenth transistor T10 is connected to the second clock signal end CKB.

A first electrode of the third transistor T3 is connected to the second clock signal end CKB, a second electrode of the third transistor T3 is connected to a second electrode of the seventh transistor T7, and a control electrode of the third transistor T3 is connected to the third node N3.

A first electrode of the seventh transistor T7 is connected to the second power signal end VGB, and a control electrode of the seventh transistor T7 is connected to the sixth node N6.

A first electrode of the twelfth transistor T12 is connected to the third clock signal end CKD, a second electrode of the twelfth transistor T12 is connected to the first node N1, and a control electrode of the twelfth transistor T12 is connected to the third node N3.

A first electrode of the first capacitor C1 is connected to the third node N3, and a second electrode of the first capacitor C1 is connected to a second electrode of the third transistor T3.

A first electrode of the second capacitor C2 is connected to the control electrode of the ninth transistor T9, and a second electrode of the second capacitor C2 is connected to the second electrode of the ninth transistor T9.

The fifth voltage stabilizing module 225 includes an eleventh transistor T11, a first electrode of the eleventh transistor T11 is connected to the third node N3, and a second electrode of the eleventh transistor T11 is connected to the first node N1.

It should be noted that, compared with the implementation shown in FIG. 2, in the implementation shown in FIG. 18, T11 is directly moved rightward to form a fifth voltage stabilizing module for stabilizing the voltage of the second node N2, and no voltage stabilizing module is provided ahead of the first node N1. Same or similar parts can be referred from the related description of the embodiments shown in FIG. 2.

Referring to FIG. 1 and FIG. 19, in another embodiment of this application, the control sub-circuit 20 includes a fourth control sub-module 214 and a sixth voltage stabilizing module 226.

The fourth control sub-module 214 is connected to the third node N3, the first node N1, a fifth node N5, the first power signal end VGA, the second power signal end VGB, the first clock signal end CKA, the second clock signal end CKB and the third clock signal end CKD, and is configured to control signals of the first node N1 and the fifth node N5 and provide the signal of the third node N3 to the first node N1 or the fifth node N5 in response to signals from the first power signal end VGA, the second power signal end VGB, the first clock signal end CKA, the second clock signal end CKB and the third clock signal end CKD.

The sixth voltage stabilizing module 226 is connected to the fifth node N5, the second node N2 and the first power signal end VGA, and is configured to provide a voltage of the fifth node N5 to the second node N2 in response to a signal from the first power signal end VGA.

Still referring to FIG. 19, the fourth control sub-module 214 includes a first transistor T1, a sixth transistor T6, an eighth transistor T8, a ninth transistor T9, a tenth transistor T10, a third transistor T3, a seventh transistor T7, an eleventh transistor T11, a twelfth transistor T12, a first capacitor C1 and a second capacitor C2.

A first electrode of the first transistor T1 is connected to the first clock signal end CKA, a second electrode of the first transistor T1 is connected to a sixth node N6, and a control electrode of the first transistor T1 is connected to the third node N3.

A first electrode of the sixth transistor T6 is connected to the first power signal end VGA, a second electrode of the sixth transistor T6 is connected to the sixth node N6, and a control electrode of the sixth transistor T6 is connected to the first clock signal end CKA.

A first electrode of the eighth transistor T8 is connected to the sixth node N6, a second electrode of the eighth transistor T8 is connected to a control electrode of the ninth transistor T9, and a control electrode of the eighth transistor T8 is connected to the first power signal end VGA.

A first electrode of the ninth transistor T9 is connected to the second clock signal end CKB, and a second electrode of the ninth transistor T9 is connected to a first electrode of the tenth transistor T10.

A second electrode of the tenth transistor T10 is connected to the first node N1, and a control electrode of the tenth transistor T10 is connected to the second clock signal end CKB.

A first electrode of the third transistor T3 is connected to the second clock signal end CKB, a second electrode of the third transistor T3 is connected to a second electrode of the seventh transistor T7, and a control electrode of the third transistor T3 is connected to the fifth node N5.

A first electrode of the seventh transistor T7 is connected to the second power signal end VGB, and a control electrode of the seventh transistor T7 is connected to the sixth node N6.

A first electrode of the eleventh transistor T11 is connected to the third node N3, a second electrode of the eleventh transistor T11 is connected to the fifth node N5, and a control electrode of the eleventh transistor T11 is connected to the first power signal end CKA.

A first electrode of the twelfth transistor T12 is connected to the third clock signal end CKD, a second electrode of the twelfth transistor T12 is connected to the first node N1, and a control electrode of the twelfth transistor T12 is connected to the fifth node N5.

A first electrode of the first capacitor C1 is connected to the fifth node N5, and a second electrode of the first capacitor C1 is connected to a second electrode of the third transistor T3.

A first electrode of the second capacitor C2 is connected to the control electrode of the ninth transistor T9, and a second electrode of the second capacitor C2 is connected to the second electrode of the ninth transistor T9.

The sixth voltage stabilizing module 226 includes a seventeenth transistor T17, a first electrode of the seventeenth transistor T17 is connected to the fifth node N5, and a second electrode of the seventeenth transistor T17 is connected to the first node N1.

It should be noted that, compared with the implementation shown in FIG. 2, in the implementation shown in FIG. 19, no voltage stabilizing module is disposed ahead of the first node N1. Same or similar parts can be referred from the related description of the embodiments shown in FIG. 2.

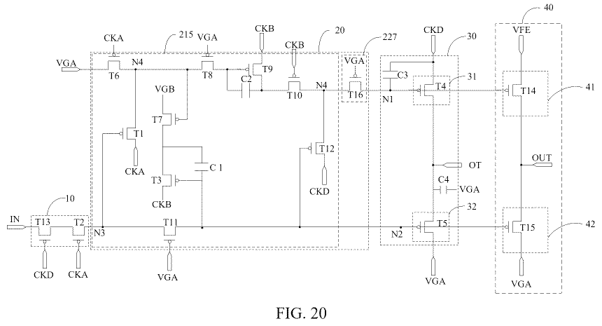

Referring to FIG. 1 and FIG. 20, in another embodiment of the present disclosure, the control sub-circuit 20 includes a fifth control sub-module 215 and a seventh voltage stabilizing module 227.

The fifth control sub-module 215 is connected to the third node N3, a fourth node N4, a second node N2, the first power signal end VGA, the second power signal end VGB, the first clock signal end CKA, the second clock signal end CKB and the third clock signal end CKD, and is configured to control signals of the fourth node N4 and the second node N2 and provide the signal of the third node N3 to the fourth node N4 or the second node N2 in response to signals from the first power signal end VGA, the second power signal end VGB, the first clock signal end CKA, the second clock signal end CKB and the third clock signal end CKD.

The seventh voltage stabilizing module 227 is connected to the fourth node N4, the first node N1 and the first power signal end VGA, and is configured to provide a voltage of the fourth node N4 to the first node N1 in response to a signal from the first power signal end VGA.

Still referring to FIG. 20, the fifth control sub-module 215 includes a first transistor T1, a sixth transistor T6, an eighth transistor T8, a ninth transistor T9, a tenth transistor T10, a third transistor T3, a seventh transistor T7, an eleventh transistor T11, a twelfth transistor T12, a first capacitor C1 and a second capacitor C2.

A first electrode of the first transistor T1 is connected to the first clock signal end CKA, a second electrode of the first transistor T1 is connected to a sixth node N6, and a control electrode of the first transistor T1 is connected to the third node N3.

A first electrode of the sixth transistor T6 is connected to the first power signal end VGA, a second electrode of the sixth transistor T6 is connected to the sixth node N6, and a control electrode of the sixth transistor T6 is connected to the first clock signal end CKA.

A first electrode of the eighth transistor T8 is connected to the sixth node N6, a second electrode of the eighth transistor T8 is connected to a control electrode of the ninth transistor T9, and a control electrode of the eighth transistor T8 is connected to the first power signal end VGA.

A first electrode of the ninth transistor T9 is connected to the second clock signal end CKB, and a second electrode of the ninth transistor T9 is connected to a first electrode of the tenth transistor T10.

A second electrode of the tenth transistor T10 is connected to the fourth node N4, and a control electrode of the tenth transistor T10 is connected to the second clock signal end CKB.

A first electrode of the third transistor T3 is connected to the second clock signal end CKB, a second electrode of the third transistor T3 is connected to a second electrode of the seventh transistor T7, and a control electrode of the third transistor T3 is connected to the second node N2.

A first electrode of the seventh transistor T7 is connected to the second power signal end VGB, and a control electrode of the seventh transistor T7 is connected to the sixth node N6.

A first electrode of the eleventh transistor T11 is connected to the third node N3, a second electrode of the eleventh transistor T11 is connected to the second node N2, and a control electrode of the eleventh transistor T11 is connected to the first power signal end CKA.

A first electrode of the twelfth transistor T12 is connected to the third clock signal end CKD, a second electrode of the twelfth transistor T12 is connected to the fourth node N4, and a control electrode of the twelfth transistor T12 is connected to the second node N2.

A first electrode of the first capacitor C1 is connected to the second node N2, and a second electrode of the first capacitor C1 is connected to a second electrode of the third transistor T3.

A first electrode of the second capacitor C2 is connected to the control electrode of the ninth transistor T9, and a second electrode of the second capacitor C2 is connected to the second electrode of the ninth transistor T9.

The seventh voltage stabilizing module 227 includes a sixteenth transistor T16, where a first electrode of the sixteenth transistor T16 is connected to the fourth node N4, a second electrode of the sixteenth transistor is connected to the first node N1, and a control electrode of the sixteenth transistor T16 is connected to the first power signal end VGA.

It should be noted that, compared with the implementation shown in FIG. 2, in the implementation shown in FIG. 20, the voltage stabilizing module including the seventeenth transistor T17 is not disposed ahead of the second node N2. Same or similar parts can be referred from the related description of the embodiments shown in FIG. 2.

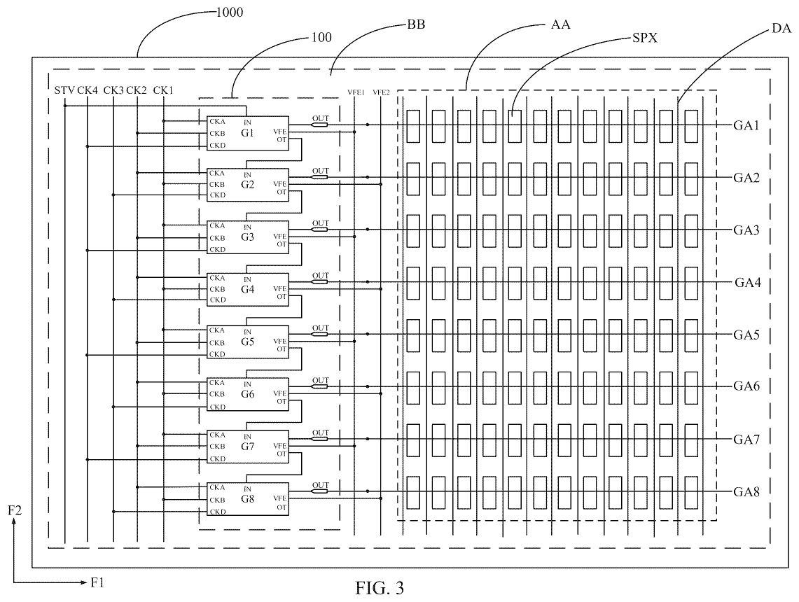

As shown in FIG. 3, the present disclosure further provides a display panel including a display area AA and a non-display area BB. The display area AA includes a plurality of sub-pixels and a plurality of scanning lines GA connected to the sub-pixels. Each row of the sub-pixels is connected to one of the scanning lines GA (a row direction is F1 direction shown in FIG. 3). The one of the scanning lines GA transmits a gate scanning signal to the row of the sub-pixels coupled thereto for driving the row of the sub-pixels. The non-display area BB includes a gate driving circuit 100, the gate driving circuit 100 includes a plurality of shift register units (for example, G1, G2, G3, G4, G5, G7, G8 in FIG. 3) arranged along a column direction (a direction F2 shown in FIG. 3), and a driving output end OUT of each of the shift register units is correspondingly coupled to at least one of the scanning lines GA. For two adjacent shift register units, an input signal end IN of a latter one of the two shift register units is coupled to a cascade output end OT of a former one of the shift register units. In an optional embodiment, the driving output end OUT of each of the shift register units is correspondingly coupled to two scanning lines GA. In the above-mentioned shift register units, an input signal end IN of one of the shift register units is correspondingly coupled to a cascade output end OT of a previous shift register unit. The input signal end IN of a first shift register unit is coupled to a reset signal line STV.

As shown in FIG. 3, in some embodiments, the display panel further includes a plurality of control signal lines (VFE1, VFE2) coupled to the gate driving circuit 100. An extending direction of each of the control signal lines is same as an arrangement direction of the shift register units. An extending direction of each of the control signal lines is same as an arrangement direction of the shift register units. The control signal lines include a first control sub-signal line VFE1 and a second control sub-signal line VFE2.

The first control sub-signal line VFE1 is coupled to the control signal ends VFE of odd-numbered shift register units, and the second control sub-signal line is coupled to the control signal ends VFE of even-numbered shift register units.

As shown in FIG. 3, in some embodiments, the display panel further includes a plurality of clock signal lines (CK1, CK2, CK3, CK4) coupled to the gate driving circuit 100. An extending direction of each of the clock signal lines is same as an arrangement direction of the shift register units. The clock signal lines include a first clock signal line CK1, a second clock signal line CK2, a third clock signal line CK3, and a fourth clock signal line CK4.

The first clock signal ends CKA of odd-numbered shift register units and the second clock signal ends CKB of even-numbered shift register units are coupled to the first clock signal line CK1. The second clock signal ends CKB of the odd-numbered shift register units and the first clock signal ends CKA of the even-numbered shift register units are coupled to the second clock signal line CK2. The third clock signal ends CKD of the odd-numbered shift register units are coupled to the fourth clock signal line CK4. The third clock signal ends CKD of the even-numbered shift register units are coupled to the third clock signal line CK3.

In an optional embodiment, the display panel further includes a plurality of power signal lines (VGA, VGB) coupled to the gate driving circuit 100, and an extending direction of each of the power signal lines is same as an arrangement direction of the shift register units.

In some embodiments, the display panel further includes a plurality of auxiliary control signal lines (VFE3, VFE4). An insulating layer is disposed between the plurality of auxiliary control signal lines and the plurality of control signal lines. The auxiliary control signal lines are in one-to-one correspondence with the control signal lines, and the auxiliary control signal line(s) and the corresponding control signal line(s) are coupled to each other by holes penetrating through the insulating layer. For example, in some embodiments, the auxiliary control signal lines include a first auxiliary control signal line VFE3 and a second auxiliary control signal line VFE4. The first auxiliary control signal line VFE3 is coupled to the first control sub-signal line VFE1, and the second auxiliary control signal line VFE4 is coupled to the second control sub-signal line VFE2.

In some embodiments, the display panel further includes a plurality of auxiliary clock signal lines (CK5, CK6, CK7, CK8). An insulating layer is disposed between the plurality of auxiliary clock signal lines and the plurality of clock signal lines. The auxiliary clock signal lines are in one-to-one correspondence with the clock signal lines, and the auxiliary clock signal line(s) and the corresponding clock signal line(s) are coupled to each other by holes penetrating through the insulating layer. For example, in some embodiments, the auxiliary clock signal lines include a first auxiliary clock signal line CK5, a second auxiliary clock signal line CK6, a third auxiliary clock signal line CK7, and a fourth auxiliary clock signal line CK8. The first auxiliary clock signal line CK5 is coupled to the first clock signal line CK1. The second auxiliary clock signal line CK6 is coupled to the second clock signal line CK2. The third auxiliary clock signal line CK7 is coupled to the third clock signal line CK3. The fourth auxiliary clock signal line CK8 is coupled to the fourth clock signal line CK4.

In some embodiments, the display panel further includes an auxiliary reset signal line. An insulating layer is disposed between the auxiliary reset signal line and the reset signal line, and the auxiliary reset signal line and the reset signal line are coupled through a through hole penetrating the insulating layer. For example, in some embodiments, the auxiliary reset signal line includes an auxiliary reset signal line STV1, and the auxiliary reset signal line STV1 is coupled to the reset signal line STV.

In some embodiments, the auxiliary control signal lines, the auxiliary clock signal lines, and the auxiliary reset signal lines may be disposed in a same layer, that is, formed by etching a same metal layer.

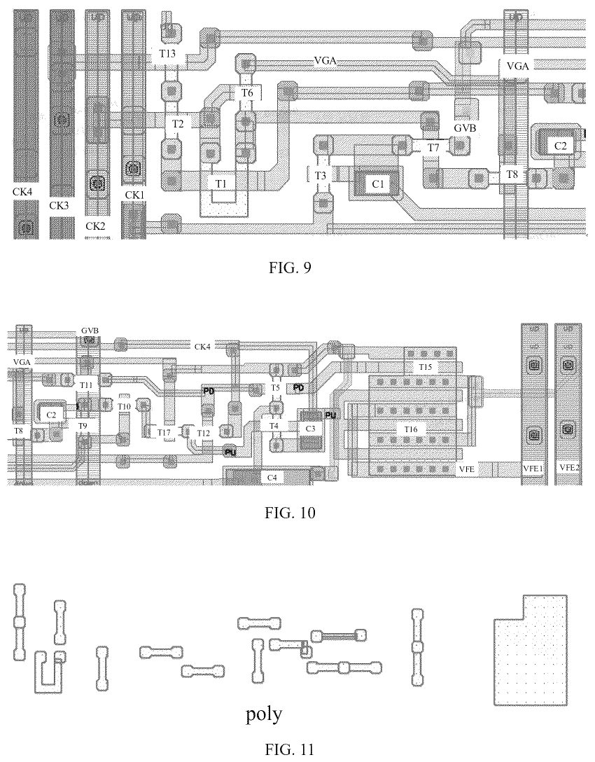

As shown in FIG. 3 and FIG. 8 to FIG. 16, in some alternative embodiments, the display panel includes a substrate 1000, and an active layer (poly), a gate layer (gate1), a capacitor electrode layer (gate2), a cascade layer (gate3), a signal transmission wiring layer (SD1), and an auxiliary wiring layer (SD2) are sequentially disposed on the substrate 1000. An insulating layer is disposed between every two adjacent layers of the active layer (poly), the gate layer (gate1), the capacitor electrode layer (gate2), the cascade layer (gate3), the signal transmission wiring layer (SD1) and the auxiliary wiring layer (SD2). The every two layers need to be coupled, and are therefore coupled to each other through a through hole penetrating through the insulating layer.

As shown in FIG. 11, the active layer (poly) is provided with channels of all transistors. Optionally, the active layer (poly) may be made of amorphous silicon, polysilicon, an oxide semiconductor material, or the like. The active layer (poly) may selectively perform n-type doping or p-type doping on a local region to meet requirement of forming a transistor.

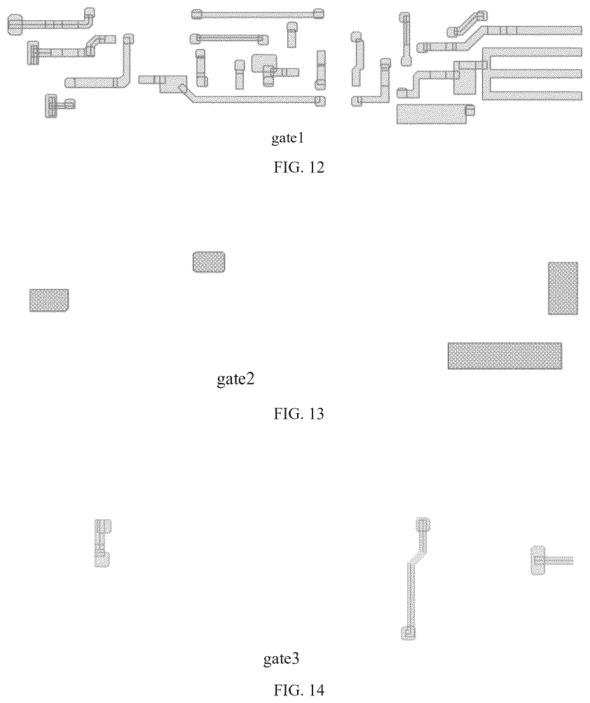

As shown in FIG. 12, the gate layer (gate1) includes a gate electrode and a scanning line in each transistor described above. Gates of some of the transistors are reused as a plate of the above mentioned capacitor.

As shown in FIG. 13, the capacitor electrode layer (gate2) includes another electrode plate in each capacitor. Two plates with areas facing each other form the capacitor.

As shown in FIG. 14, the cascade layer (gate3) includes cascade wires for coupling the input signal end IN of a next shift register unit with the first output signal end OUTA of a previous shift register unit.

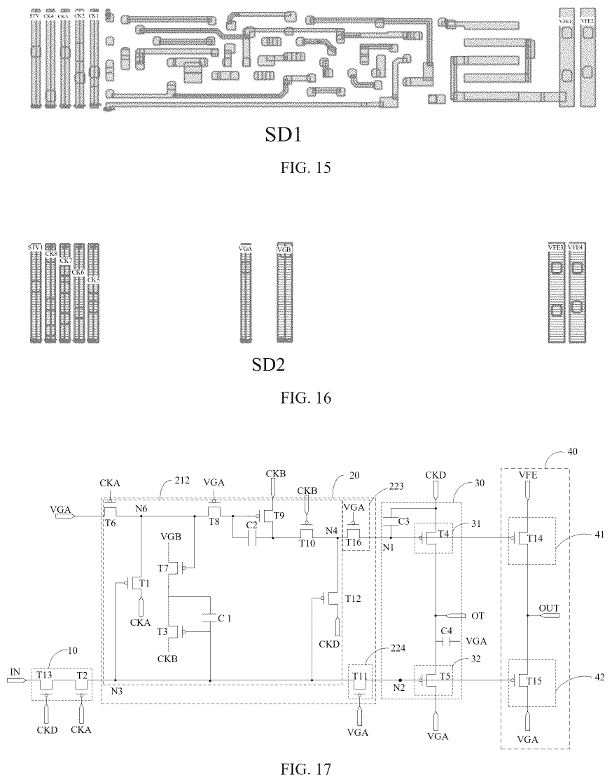

As shown in FIG. 15, the signal transmission wiring layer (SD1) includes a clock signal line, a control signal line, and a source and a drain in each of the above transistors.

As shown in FIG. 16, the auxiliary wiring layer (SD2) includes auxiliary control signal lines (VFE3, VFE4), power signal lines (VGA, VGB), auxiliary clock signal lines (CK5, CK6, CK7, CK1) and auxiliary reset signal lines (STV 1).

In some embodiments, an orthographic projection of the control signal lines (VFE1, VFE2) on the substrate 1000 is located between an orthographic projection of the gate driving circuit 100 on the substrate 1000 and the display area AA.

An orthographic projection of the gate driving circuit 100 on the substrate 1000 is located between an orthographic projection of the clock signal lines (CK1, CK2, CK3, CK4) on the substrate 1000 and the orthographic projection of the control signal lines (VFE1, VFE2) on the substrate 1000.

An orthographic projection of the fourteenth transistor T14 on the substrate 1000 is located between an orthographic projection of the fourth transistor T4 on the substrate 1000 and the display area AA. An orthographic projection of the fifteenth transistor T15 on the substrate 1000 is located between an orthographic projection of the fifth transistor T5 on the substrate 1000 and the display area AA. Optionally, an orthographic projection of the fourteenth transistor T14 on the substrate 1000 is located between an orthographic projection of the fourth transistor T4 on the substrate 1000 and the orthographic projection of the control signal lines (VFE1, VFE2) on the substrate 1000. An orthographic projection of the fifth transistor T15 on the substrate 1000 is located between an orthographic projection of the fifth transistor T5 on the substrate 1000 and the orthographic projection of the control signal lines (VFE1, VFE2) on the substrate 1000.

It should be noted that the fourteenth transistor T14 and the fifteenth transistor T15 are larger than the fourth transistor T4 and the fifth transistor T5, so as to ensure the output function of the driving output end OUT. For example, transistors such as the fourth transistor T4 and the fifth transistor T5 may be transistors selected with a ratio of a width W to a length L being W/L=3/3.5. The fourteenth transistor T14 and the fifteenth transistor T15 are selected to have a ratio of the width W to the length L more than 3/3.5.

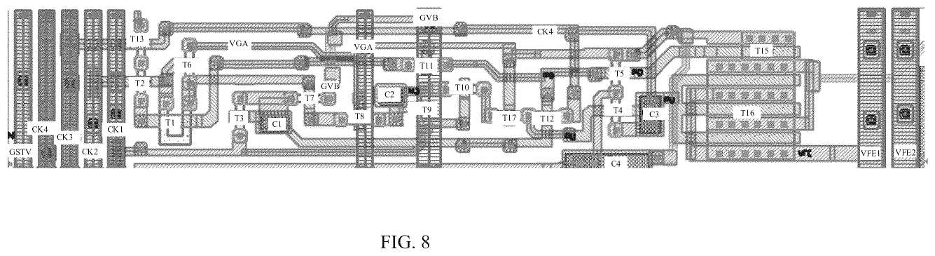

Referring to FIG. 8 and FIG. 10, in some embodiments, a channel width of the fourteenth transistor T14 is greater than a channel width of the fourth transistor T4.

In some embodiments, the channel width of the fourteenth transistor T14 is not less than 100 μm.

In some embodiments, the channel width of the fourth transistor T4 is not greater than 60 μm.

In some embodiments, a channel width of the fifteenth transistor T15 is greater than a channel width of the fifth transistor T5.

In some embodiments, the channel width of the fifteenth transistor T15 is not less than 100 μm.

In some embodiments, the channel width of the fifth transistor T5 is not greater than 60 μm.

The orthographic projection of the power signal lines (VGA, VGB) on the substrate 1000 are located between the orthographic projection of the control signal lines (VFE1, VFE2) on the substrate 1000 and the orthographic projection of the clock signal lines (CK1, CK2, CK3, CK4) on the substrate 1000.

In some embodiments, an orthographic projection of the first auxiliary control signal line VFE3 on the substrate 1000 overlaps with an orthographic projection of the control sub-signal line VFE1 on the substrate 1000, and an orthographic projection of the second auxiliary control signal line VFE4 on the substrate 1000 overlaps with an orthographic projection of the second control sub-signal line VFE2 on the substrate 1000. The first auxiliary control signal line VFE3 is coupled to the first control sub-signal line VFE1 through a through hole of the insulating layer. The second auxiliary control signal line VFE4 is coupled to the second control sub-signal line VFE2 through a through hole of the insulating layer.

In some embodiments, an orthographic projection of the first auxiliary clock signal line CK5 on the substrate 1000 overlaps with an orthographic projection of the first clock signal line CK1 on the substrate 1000. An orthographic projection of the second auxiliary clock signal line CK6 on the substrate 1000 overlaps with an orthographic projection of the second clock signal line CK2 on the substrate 1000. An orthographic projection of the third auxiliary clock signal line CK7 on the substrate 1000 overlaps with an orthographic projection of the third clock signal line CK3 on the substrate 1000. An orthographic projection of the fourth auxiliary clock signal line CK8 on the substrate 1000 overlaps with an orthographic projection of the fourth clock signal line CK4 on the substrate 1000.

In some embodiments, an orthographic projection of the auxiliary reset signal line STV1 on the substrate 1000 overlaps with an orthographic projection STV of the reset signal line on the substrate 1000.

The overlapping herein may be understood as partial area overlapping or full area overlapping.

In some embodiments, an orthographic projection of the fourth capacitor C4 on the substrate 1000 is located on a side of the shift register unit close to a next shift register unit.

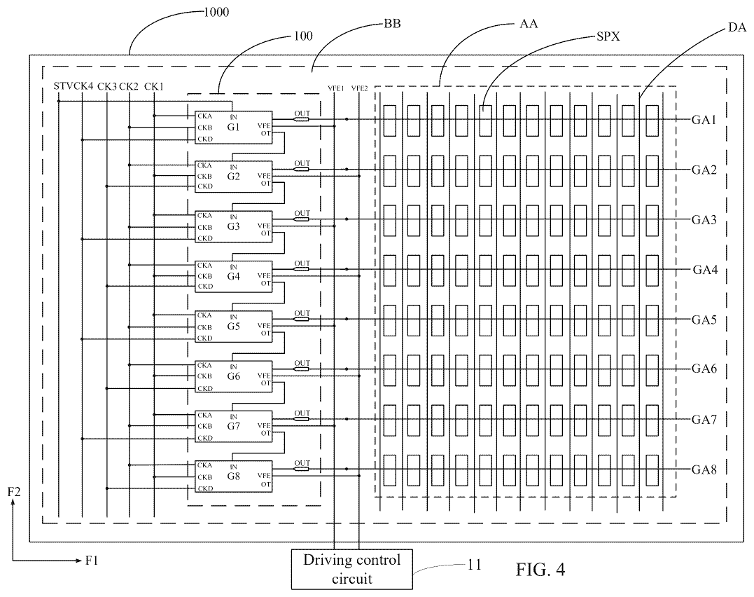

As shown in FIG. 4, the present disclosure further provides a display apparatus including the display panel and the driving control circuit 11 described above.

The driving control circuit 11 is coupled to the display panel and configured to input a first signal to the control signal ends VFE of the shift register units (e.g., G1, G2, G3, G4, G5, G6, G7, G8 in FIG. 4) when determining that a full-screen refresh mode is adopted, so that the shift register units (e.g., G1, G2, G3, G4, G5, G6, G7, G8 in FIG. 4) sequentially output gate scanning signals to drive the scanning lines GA row by row.

When it is determined that a partition refresh mode is adopted, a second signal is input to the control signal ends VFE of the shift register units (e.g., G1, G2, G3, G4, G5, G6, G7, G8 in FIG. 4), so that part of the shift register units (e.g., G1, G2, G3, G4, G5, G6, G7, G8 in FIG. 4) sequentially output gate scanning signals, and rest of the shift register units output invalid scanning signals. Illustratively, the second signal is input to the control signal ends VFE of the shift register units G1, G2, G3, G4, G5, G6, G7, G8, so that the shift register units G1, G2, G3, and G4 sequentially output gate scanning signals, and rest of the shift register units G5, G6,G7,G8 output invalid scanning signals.

Illustratively, the gate scanning signal is a high-level signal, and the invalid scanning signal is a low-level signal; alternatively, the gate scanning signal is a low-level signal, and the invalid scanning signal is a high-level signal, which is not limited herein.

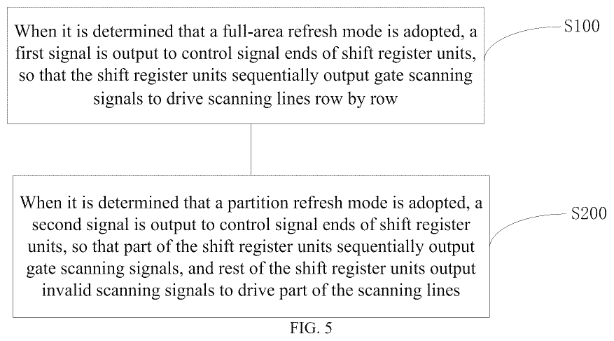

Referring to FIG. 5, the present disclosure further provides a driving method, which may be applied to the above display apparatus or the display panel, and may include following steps S100 and S200.

In step S100, when it is determined that a full-area refresh mode is adopted, a first signal is output to the control signal ends VFE of the shift register units (e.g., G1, G2, G3, G4, G5, G6, G7, G8 in FIG. 4), so that the shift register units (e.g., G1, G2, G3, G4, G5, G6, G7 and G8 in FIG. 4) sequentially output gate scanning signals to drive scanning lines row by row.

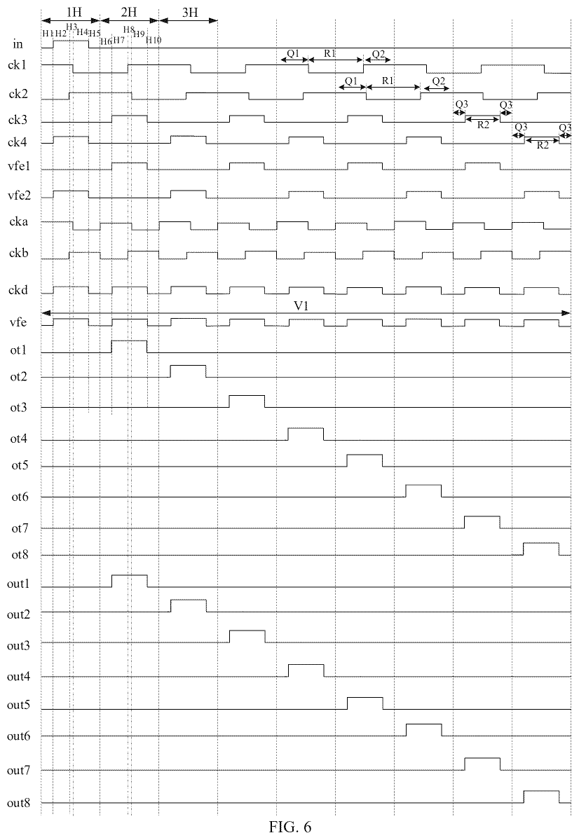

As shown in FIG. 6, in some embodiments, the first signal is a clock signal, such as a V1 signal in FIG. 6. For example, the clock signal may alternate between a first electrical level and a second electrical level.

In S200, when it is determined that a partition refresh mode is adopted, a second signal is output to the control signal ends of the shift register units (e.g., G1, G2, G3, G4, G5, G6, G7, G8 in FIG. 4), so that part of the shift register units (e.g., G1, G2, G3, G4, G5, G6, G7, G8 in FIG. 4) sequentially output gate scanning signals, and rest of the shift register units output invalid scanning signals to drive part of the scanning lines.

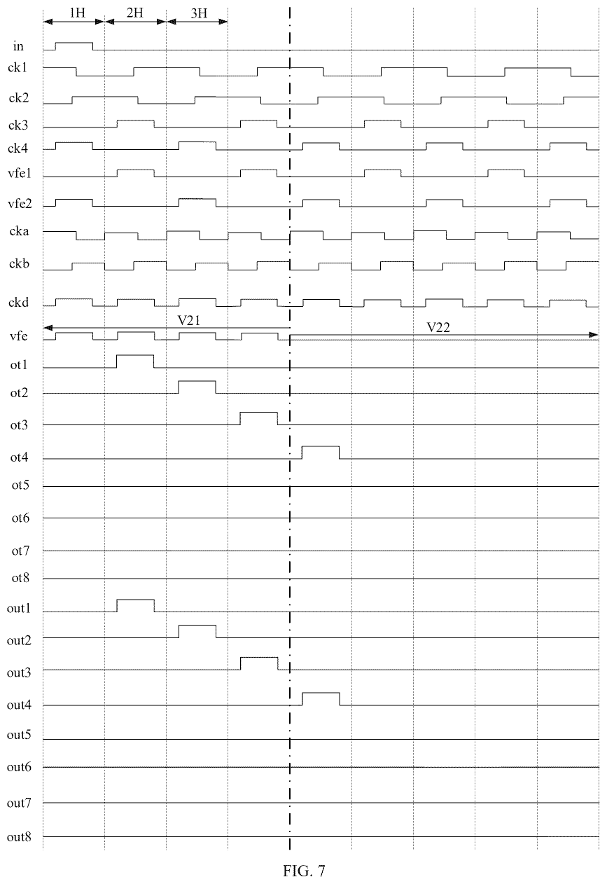

As shown in FIG. 7, in some embodiments, the second signal includes a fixed signal portion including a clock signal and a fixed signal portion including a second electrical level. The second electrical level is an electrical level of the invalid gate scanning signal. The fixed signal portion including the clock signal is input into part of the shift register units, and the fixed signal portion including the second electrical level is input into rest of the shift register units. For example, as shown in FIG. 7, the second signal includes a fixed signal portion V2 including a clock signal and a fixed signal portion V3 including a second electrical level. The second signal inputs valid signals to the shift register units G1, G2, G3 and G4, so that the shift register units G1, G2, G3 and G4 sequentially output valid gate scanning signals and drive the scanning lines row by row; and inputs invalid signals to the shift register units G5, G6, G7 and G8, so that the shift register units G5, G6, G7 and G8 output invalid scanning signals to drive part of the scanning lines. For example, the fixed portion including the clock signal may alternate between a first electrical level and a second electrical level.

Optionally, the gate scanning signal is a high-level signal, and the invalid scanning signal is a low-level signal; alternatively, the gate scanning signal is a low-level signal, and the invalid scanning signal is a high-level signal, which is not limited herein.

The structure of the shift register unit shown in FIG. 2 is taken as an example, with reference to a signal timing diagram shown in FIG. 6, and also with reference to FIG. 3 and FIG. 4 when necessary, an operation process of the shift register unit provided by the embodiment of the present disclosure will be described.

The control signal lines include a first control sub-signal line VFE1 and a second control sub-signal line VFE2. The first control sub-signal line VFE1 is coupled to the control signal ends VFE of odd-numbered shift register units, and the second control sub-signal line VFE2 is coupled to the control signal ends VFE of even-numbered shift register units. For example, the first control sub-signal line VFE1 is coupled to the control signal ends VFE of the shift register units G1, G3, G5 and G7. The second control sub-signal line VFE2 is coupled to the control signal ends VFE of the shift register units G2, G4, G6 and G8. The clock signal lines include a first clock signal line CK1, a second clock signal line CK2, a third clock signal line CK3, and a fourth clock signal line CK4. The first clock signal ends CKA of odd-numbered shift register units and the second clock signal ends CKB of even-numbered shift register units are coupled to the first clock signal line CK1. The second clock signal ends CKB of the odd-numbered shift register units and the first clock signal ends CKA of the even-numbered shift register units are coupled to the second clock signal line CK2. The third clock signal ends CKD of the odd-numbered shift register units are coupled to the fourth clock signal line CK4. The third clock signal ends CKD of the even-numbered shift register units are coupled to the third clock signal line CK3. For example, the first clock signal ends CKA of the shift register units G1, G3, G5 and G7 and the second clock signal ends CKB of the shift register units G2, G4, G5 and G7 are coupled to the first clock signal line CK1. The second clock signal ends CKB of the shift register units G1, G3, G5, G7 and the first clock signal ends CKA of the shift register units G2, G4, G6, G8 are coupled to the second clock signal line CK2. The third clock signal ends CKD of the shift register units G1, G3, G5 and G7 are coupled to the fourth clock signal line CK4. The third clock signal ends CKD of the shift register units G2, G4, G6 and G8 are coupled to the third clock signal line CK3.

It is taken as an example for description that all transistors are P-type transistors, a valid pulse signal of a signal output by the first power sub-signal end VGA is a low level signal, a valid pulse signal of a signal output by the second power sub-signal end VGB is a low level signal, the first signal is a clock signal with alternating first electrical level and second electrical level, and the second signal includes a fixed signal portion including a clock signal with alternating first electrical level and second electrical level and a fixed signal portion including a second electrical level, where the first electrical level is a high level and the second electrical level is a low level.

Where “in” represents an input signal of the input signal end IN, “ck1” represents a clock signal output by the first clock signal line CK1, “ck2” represents the clock signal output by the second clock signal end CK2, “ck3” represents a clock signal output by the third clock signal line CK3, and “ck4” represents a clock signal output by the fourth clock signal end CK4. Where “cka” represents a first clock signal of the first clock signal end CLKA, “ckb” represents a second clock signal of the second clock signal end CLKB, and “ckd” represents a third clock signal of the third clock signal end CKD. Where “ck3” and “ck4” are alternately connected to the third clock signal end CKD between two adjacent stages. “ck1” and “ck2” are alternately connected to the first clock signal end CKA between two adjacent stages, “ck2” and “ck1” are alternately connected to the second clock signal end CKB between two adjacent stages, “vfe1” represents a control signal output by the control signal line VFE1, and “vfe2” represents a control signal output by the second control signal line VFE2. “vfe” represents a control signal output by the control signal end VFE. “otn” represents a cascade signal output by the cascade output end OT in the n-th shift register unit Gn. “outn” represents a gate scanning signal output by the driving signal end OUT in the n-th shift register unit Gn.

Since the control electrodes of the eighth transistor T8, the eleventh transistor T11, the sixteenth transistor T16, and the seventeenth transistor T17 are all coupled to the first power signal end VGA, and the first power signal end VGA is a signal end keeping a low level output, the eighth transistor T8, the eleventh transistor T11, the sixteenth transistor T16, and the seventeenth transistor T17 are normally-on transistors. Therefore, the on-off states of the eighth transistor T8, the eleventh transistor T11, the sixteenth transistor T16, and the seventeenth transistor T17 will not be analyzed hereinafter.

Based on the shift register unit shown in FIG. 2, in a first phase H1, the clock signal ck1 remains at a high level, the clock signal ck2 remains at a low level, the clock signal ck4 remains at a low level, the input signal “in” remains at a low level, and the third node N3 is connected to the input signal end IN, so that the third node N3 remains at a low level. In response to the VGA, the eleventh transistor T11 keeps the potential of the fifth node N5 at the low level. Under control of the potential of the fifth node N5, the twelfth transistor T12 is turned on, the fourth node N4 is connected to the third power sub-signal end CKD, the fourth node N4 remains at a low level, and the first node N1 remains at a low level. Under control of the potential of the fifth node N5, the second node N2 remains at a low level. The first output signal end OT outputs a low level signal, and the second output signal end OUT outputs a low level signal.

In a second phase H2, the clock signal ck1 remains at a high-level, the clock signal ck2 remains at a low-level, the clock signal ck4 remains at a high-level, and the input signal “in” remains at a high-level. The third node N3 is at a high level. In response to the VGA, the eleventh transistor T11 keeps the potential of the fifth node N5 at a high level. The second node N2 remains at a high level. The fourth node N4 remains at a low level, and the first node N1 remains at a low level. The first output signal end OT outputs a low level signal, and the second output signal end OUT outputs a low level signal.

In a third phase H3, the clock signal ck1 remains at a high-level, the clock signal ck2 remains at a high-level, the clock signal ck4 remains at a high-level, and the input signal “in” remains at a high-level. The third node N3 remains at a low-level, the fifth node N5 and the second node N2 remain at a low-level, the sixth node remains at a high-level, the fourth node N4 remains at a high-level, and the first node N1 remains at a high-level. The first output signal end OT outputs a low level signal, and the second output signal end OUT outputs a low level signal.

In a fourth phase H4, the clock signal ck1 remains at a low-level, the clock signal ck2 remains at a high-level, the clock signal ck4 remains at a high-level, and the input signal “in” remains at a high-level. The third node N3 remains at a low level. The fifth node N5 and the second node N2 remain at a low level. The fourth node remains at a high level, and the first node N1 remains at a high level. The first output signal end OT outputs a low level signal, and the second output signal end OUT outputs a low level signal.

In a fifth phase H5, the clock signal ck1 remains at a low-level, the clock signal ck2 remains at a high-level, the clock signal ck4 remains at a low-level, and the input signal “in” remains at a low-level. The third node N3 remains at a low level. The fifth node N5 and the second node N2 remain at a low level. The fourth node remains at a high level, and the first node N1 remains at a high level. The first output signal end OT outputs a low level signal, and the second output signal end OUT outputs a low level signal.

Similarly, in a sixth phase H6, the clock signal ck1 remains at a low level, the clock signal ck2 remains at a high level, the clock signal ck4 remains at a low level, and “in” remains at a low level. The third node N3 remains at a low level, and the fifth node N5 and the second node N2 remain at a low level. The sixth node N6 remains at a low level, the fourth node N4 remains at a low level, and the first node N1 remains at a low level. The first output signal end OT outputs a low level signal, and the second output signal end OUT outputs a low level signal.

In a seventh phase H7, the clock signal ck1 remains at a low level, the clock signal ck2 remains at a low level, the clock signal ck4 remains at a low level, and “in” remains at a low level. The third node N3 remains at a low level, and the fifth node N5 and the second node N2 remain at a low level. The sixth node N6 remains at a low level, the fourth node N4 remains at a low level, and the first node N1 remains at a low level. The first output signal end OT outputs a high level signal, and the second output signal end OUT outputs a high level signal.

In an eighth phase H8, the clock signal ck1 remains at a high level, the clock signal ck2 remains at a high level, the clock signal ck4 remains at a low level, and “in” remains at a low level. The third node N3 remains at a low level, and the fifth node N5 and the second node N2 remain at a low level. The sixth node N6 remains at a high level, the fourth node N4 remains at a low level, and the first node N1 remains at a low level. The first output signal end OT outputs a high level signal, and the second output signal end OUT outputs a high level signal.

In a ninth phase H9, the clock signal ck1 remains at a high level, the clock signal ck2 remains at a low level, the clock signal ck4 remains at a low level, and “in” remains at a low level. The third node N3 remains at a low level, and the fifth node N5 and the second node N2 remain at a low level. The sixth node N6 remains at a high level, the fourth node N4 remains at a low level, and the first node N1 remains at a low level. The first output signal end OT outputs a high level signal, and the second output signal end OUT outputs a high level signal.

In a tenth phase H10, the clock signal ck1 remains at a high level, the clock signal ck2 remains at a low level, the clock signal ck4 remains at a low level, and “in” remains at a low level. The third node N3 remains at a low level, and the fifth node N5 and the second node N2 remain at a low level. The sixth node N6 remains at a high level, the fourth node N4 remains at a low level, and the first node N1 remains at a low level. The first output signal end OT outputs a low level signal, and the second output signal end OUT outputs a low level signal.

As shown in FIG. 6, in some embodiments, the valid gate scanning signal output by a next shift register unit is 1H later than the valid gate scanning signal output by a previous shift register unit, where 1H=2.73 μs. A pulse width of the input signal “in” is R2=1.73 μs. A period of the clock signal ck1 output by the first clock signal line CK1 is 2H, a high-level pulse width of the clock signal ck1 is Q1+Q2, a low-level pulse width of the clock signal ck1 is R1, where R1=2.13 μs, Q1=1.66 μs, and Q2=1.67 μs. A period of the clock signal ck2 output by the second clock signal line CK2 is 2H, a high-level pulse width thereof is also Q1+Q2, and a low-level pulse width thereof is also R1. A period of the clock signal ck3 output by the third clock signal line CK3 is 2H. The clock signal ck4 output by the fourth clock signal line CK4 is a clock signal alternating between a 1H clock signal and a 1H low level signal. For ck4, a high level pulse width of the clock signal alternating with the low level signal is R2=1.73 s, and low level pulse widths connected to the low level signals on two adjacent sides are Q3=0.5 μs. The first clock signal cka of the first clock signal end CKA is a clock signal alternating between ck1 and ck2. The second clock signal ckb of the first clock signal end CKB is a clock signal alternating between ck1 and ck2. The third clock signal ckd of the third clock signal end CKD is a clock signal alternating between ck3 and ck4. vfe1 is consistent with ck3, and vfe2 is consistent with ck4. ck1, ck2, ck3, ck4, cka, ckb, ckd, vfe1 and vfe2 are specifically shown in FIG. 6.

For example, in a display panel with 1024 rows of pixels, there are 512 shift register units in total, and each shift register unit controls two rows of pixels. Each eight adjacent shift register units form one group, and there are 64 groups in total. The control signal ends VFE of the odd-numbered groups of shift register units are all coupled to the first control sub-signal line VFE1, and the control signal ends VFE of the even-numbered groups of shift register units are all coupled to the second control sub-signal line VFE2. When the first control sub-signal line VFE1 and the second control sub-signal line VFE2 are controlled to output the second signal, the shift register units of the first to thirty-second groups output valid gate scanning signals in each of 120 frames, and the shift register units of the thirty-third to sixty-fourth groups output valid gate scanning signals once every two of 120 frames. An area controlled by the first 512 rows of pixels of the display panel may be 120 Hz, and an area controlled by the last 512 rows of pixels may be 60 Hz, so as to implement the partition refresh. Certainly, it is also possible to control the first control sub-signal line VFE1 and the second control sub-signal line VFE2 to output a second signal, so that any group outputs a valid gate scanning signal or outputs an invalid gate scanning signal in any frame to realize the partition refresh of the display panel.

Other embodiments of the specification will be readily apparent to those skilled in the art upon consideration of the specification and practice of the present disclosure as applied herein. This specification is intended to cover any variations, uses, or adaptations of this specification that follow the general principles of this specification and include common knowledge or conventional technical means in the art not to which this specification applies. The specification and examples are to be regarded as exemplary only, and the true scope and spirit of the specification are indicated by the following claims.

It should be understood that the present specification is not limited to the precise structure described above and shown in the accompanying drawings, and various modifications and changes may be made without departing from the scope thereof. The scope of this specification is limited only by the appended claims.

The above description is only preferred embodiments of the present specification and is not intended to limit the present specification, and any modifications, equivalent substitutions, improvements, and the like made within the spirit and principle of the present specification shall fall within the protection scope of the present specification.

1. A shift register unit, comprising:
an input sub-circuit, connected to a third node, an input signal end, a first clock signal end and a third clock signal end, and configured to provide a signal of the input signal end to the third node in response to signals from the first clock signal end and the third clock signal end;
a control sub-circuit, connected to the third node, a first node, a second node, a first power signal end, a second power signal end, the first clock signal end, a second clock signal end and the third clock signal end, and configured to control signals of the first node and the second node and provide a signal of the third node to the first node or the second node in response to signals from the first power signal end, the second power signal end, the first clock signal end, the second clock signal end and the third clock signal end;
a first output sub-circuit, connected to the first node, the second node, the third clock signal end, the first power signal end and a cascade output end, and configured to enable the cascade output end to output a cascade signal in response to signals from the first node and the second node; and
a second output sub-circuit, connected to the first node, the second node, a control signal end, the first power signal end and a driving output end, and configured to enable the driving output end to output a gate scanning signal in response to signals from the first node and the second node.

2. The shift register unit according to claim 1, wherein the second output sub-circuit comprises:
a first output module, connected to the control signal end, the first node and the driving output end, and configured to transmit a signal of the control signal end to the driving output end under control of the first node; and
a second output module, connected to the first power signal end, the second node and the driving output end, and configured to transmit a signal of the first power signal end to the driving output end under control of the second node;
wherein the first output module comprises a fourteenth transistor, a first electrode of the fourteenth transistor is connected to the control signal end, a second electrode of the fourteenth transistor is connected to the driving output end, and a control electrode of the fourteenth transistor is connected to the second node;
wherein the second output module comprises a fifteenth transistor, a first electrode of the fifteenth transistor is connected to the first power signal end, a second electrode of the fifteenth transistor is connected to the driving output end, and a control electrode of the fifteenth transistor is connected to the second node.

3-4. (canceled)

5. The shift register unit according to claim 1, wherein the first output sub-circuit comprises:
a fourth transistor, wherein a first electrode of the fourth transistor is connected to the third clock signal end, a second electrode of the fourth transistor is connected to the cascade output end, and a control electrode of the fourth transistor is connected to the first node; and
a fifth transistor, wherein a first electrode of the fifth transistor is connected to the first power signal end, a second electrode of the fifth transistor is connected to the cascade output end, and a control electrode of the fifth transistor is connected to the second node;
wherein the first output sub-circuit further comprises at least one of a third capacitor or a fourth capacitor, wherein a first end of the third capacitor is connected to the first electrode of the fourth transistor, and a second end of the third capacitor is connected to the control electrode of the fourth transistor, a first end of the fourth capacitor is connected to the cascade output end, and a second end of the fourth capacitor is connected to the first power signal end.

6. (canceled)

7. The shift register unit according to claim 1, wherein the input sub-circuit comprises a thirteenth transistor and a second transistor,
wherein a first electrode of the thirteenth transistor is connected to the input signal end, a second electrode of the thirteenth transistor is connected to a first electrode of the second transistor, and a control electrode of the thirteenth transistor is connected to the third clock signal end;
a second electrode of the second transistor is connected to the third node, and a control electrode of the second transistor is connected to the first clock signal end.

8. The shift register unit according to claim 1, wherein the control sub-circuit comprises a first control sub-module, a first voltage stabilizing module and a second voltage stabilizing module,
wherein the first control sub-module is connected to the third node, a fourth node, a fifth node, the first power signal end, the second power signal end, the first clock signal end, the second clock signal end and the third clock signal end, and is configured to control signals of the fourth node and the fifth node and provide the signal of the third node to the fourth node or the fifth node in response to signals from the first power signal end, the second power signal end, the first clock signal end, the second clock signal end and the third clock signal end;
wherein the first voltage stabilizing module is connected to the fourth node, the first node and the first power signal end, and is configured to provide a voltage of the fourth node to the first node in response to a signal from the first power signal end;
wherein the second voltage stabilizing module is connected to the fifth node, the second node and the first power signal end, and is configured to provide a voltage of the fifth node to the second node in response to a signal from the first power signal end.

9. The shift register unit according to claim 8, wherein the first control sub-module comprises a first transistor, a sixth transistor, an eighth transistor, a ninth transistor, a tenth transistor, a third transistor, a seventh transistor, an eleventh transistor, a twelfth transistor, a first capacitor and a second capacitor; wherein
a first electrode of the first transistor is connected to the first clock signal end, a second electrode of the first transistor is connected to a sixth node, and a control electrode of the first transistor is connected to the third node;
a first electrode of the sixth transistor is connected to the first power signal end, a second electrode of the sixth transistor is connected to the sixth node, and a control electrode of the sixth transistor is connected to the first clock signal end;
a first electrode of the eighth transistor is connected to the sixth node, a second electrode of the eighth transistor is connected to a control electrode of the ninth transistor, and a control electrode of the eighth transistor is connected to the first power signal end;
a first electrode of the ninth transistor is connected to the second clock signal end, and a second electrode of the ninth transistor is connected to a first electrode of the tenth transistor;
a second electrode of the tenth transistor is connected to the fourth node, and a control electrode of the tenth transistor is connected to the second clock signal end;
a first electrode of the third transistor is connected to the second clock signal end, a second electrode of the third transistor is connected to a second electrode of the seventh transistor, and a control electrode of the third transistor is connected to the fifth node;
a first electrode of the seventh transistor is connected to the second power signal end, and a control electrode of the seventh transistor is connected to the sixth node;
a first electrode of the eleventh transistor is connected to the third node, a second electrode of the eleventh transistor is connected to the fifth node, and a control electrode of the eleventh transistor is connected to the first power signal end;
a first electrode of the twelfth transistor is connected to the third clock signal end, a second electrode of the twelfth transistor is connected to the fourth node, and a control electrode of the twelfth transistor is connected to the fifth node;
a first electrode of the first capacitor is connected to the fifth node, and a second electrode of the first capacitor is connected to the second electrode of the third transistor;
a first electrode of the second capacitor is connected to the control electrode of the ninth transistor, and a second electrode of the second capacitor is connected to the second electrode of the ninth transistor;
the first voltage stabilizing module comprises a sixteenth transistor, wherein a first electrode of the sixteenth transistor is connected to the fourth node, a second electrode of the sixteenth transistor is connected to the first node, and a control electrode of the sixteenth transistor is connected to the first power signal end;
the second voltage stabilizing module comprises a seventeenth transistor, wherein a first electrode of the seventeenth transistor is connected to the fifth node, a second electrode of the seventeenth transistor is connected to the first node, and a control electrode of the seventeenth transistor is connected to the first power signal end.

10. The shift register unit according to claim 1, wherein the control sub-circuit comprises a second control sub-module, a third voltage stabilizing module and a fourth voltage stabilizing module, wherein
the second control sub-module is connected to the third node, a fourth node, the first node, the first power signal end, the second power signal end, the first clock signal end, the second clock signal end and the third clock signal end, and is configured to control a signal of the fourth node and provide the signal of the third node to the fourth node in response to signals from the first power signal end, the second power signal end, the first clock signal end, the second clock signal end and the third clock signal end;
the third voltage stabilizing module is connected to the fourth node, the first node and the first power signal end, and is configured to provide a voltage of the fourth node to the first node in response to a signal from the first power signal end;
the fourth voltage stabilizing module is connected to the third node, the second node and the first power signal end, and is configured to provide a voltage of the third node to the second node in response to a signal from the first power signal end.

11. The shift register unit according to claim 10, wherein the second control sub-module comprises a first transistor, a sixth transistor, an eighth transistor, a ninth transistor, a tenth transistor, a third transistor, a seventh transistor, a twelfth transistor, a first capacitor and a second capacitor; wherein
a first electrode of the first transistor is connected to the first clock signal end, a second electrode of the first transistor is connected to a sixth node, and a control electrode of the first transistor is connected to the third node;
a first electrode of the sixth transistor is connected to the first power signal end, a second electrode of the sixth transistor is connected to the sixth node, and a control electrode of the sixth transistor is connected to the first clock signal end;
a first electrode of the eighth transistor is connected to the sixth node, a second electrode of the eighth transistor is connected to a control electrode of the ninth transistor, and a control electrode of the eighth transistor is connected to the first power signal end;
a first electrode of the ninth transistor is connected to the second clock signal end, and a second electrode of the ninth transistor is connected to a first electrode of the tenth transistor;
a second electrode of the tenth transistor is connected to the fourth node, and a control electrode of the tenth transistor is connected to the second clock signal end;
a first electrode of the third transistor is connected to the second clock signal end, a second electrode of the third transistor is connected to a second electrode of the seventh transistor, and a control electrode of the third transistor is connected to the third node;
a first electrode of the seventh transistor is connected to the second power signal end, and a control electrode of the seventh transistor is connected to the sixth node;
a first electrode of the twelfth transistor is connected to the third clock signal end, a second electrode of the twelfth transistor is connected to the fourth node, and a control electrode of the twelfth transistor is connected to the third node;
a first electrode of the first capacitor is connected to the third node, and a second electrode of the first capacitor is connected to the second electrode of the third transistor;
a first electrode of the second capacitor is connected to the control electrode of the ninth transistor, and a second electrode of the second capacitor is connected to the second electrode of the ninth transistor;
the third voltage stabilizing module comprises a sixteenth transistor, wherein a first electrode of the sixteenth transistor is connected to the fourth node, a second electrode of the sixteenth transistor is connected to the first node, and a control electrode of the sixteenth transistor is connected to the first power signal end;
the fourth voltage stabilizing module comprises an eleventh transistor, a first electrode of the eleventh transistor is connected to the third node, a second electrode of the eleventh transistor is connected to the second node, and a control electrode of the eleventh transistor is connected to the first power signal end.

12. The shift register unit according to claim 1, wherein the control sub-circuit comprises a third control sub-module and a fifth voltage stabilizing module, wherein
the third control sub-module is connected to the third node, the first node, the first power signal end, the second power signal end, the first clock signal end, the second clock signal end and the third clock signal end, and is configured to control a signal of the first node and provide the signal of the third node to the first node in response to signals from the first power signal end, the second power signal end, the first clock signal end, the second clock signal end and the third clock signal end;
the fifth voltage stabilizing module is connected to the third node, the second node and the first power signal end, and is configured to provide a voltage of the third node to the second node in response to a signal from the first power signal end.

13. The shift register unit according to claim 12, wherein the third control sub-module comprises a first transistor, a sixth transistor, an eighth transistor, a ninth transistor, a tenth transistor, a third transistor, a seventh transistor, a twelfth transistor, a first capacitor and a second capacitor; wherein
a first electrode of the first transistor is connected to the first clock signal end, a second electrode of the first transistor is connected to a sixth node, and a control electrode of the first transistor is connected to the third node;
a first electrode of the sixth transistor is connected to the first power signal end, a second electrode of the sixth transistor is connected to the sixth node, and a control electrode of the sixth transistor is connected to the first clock signal end;
a first electrode of the eighth transistor is connected to the sixth node, a second electrode of the eighth transistor is connected to a control electrode of the ninth transistor, and a control electrode of the eighth transistor is connected to the first power signal end;
a first electrode of the ninth transistor is connected to the second clock signal end, and a second electrode of the ninth transistor is connected to a first electrode of the tenth transistor;
a second electrode of the tenth transistor is connected to the first node, and a control electrode of the tenth transistor is connected to the second clock signal end;
a first electrode of the third transistor is connected to the second clock signal end, a second electrode of the third transistor is connected to a second electrode of the seventh transistor, and a control electrode of the third transistor is connected to the third node;
a first electrode of the seventh transistor is connected to the second power signal end, and a control electrode of the seventh transistor is connected to the sixth node;
a first electrode of the twelfth transistor is connected to the third clock signal end, a second electrode of the twelfth transistor is connected to the first node, and a control electrode of the twelfth transistor is connected to the third node;
a first electrode of the first capacitor is connected to the third node, and a second electrode of the first capacitor is connected to the second electrode of the third transistor;
a first electrode of the second capacitor is connected to the control electrode of the ninth transistor, and a second electrode of the second capacitor is connected to the second electrode of the ninth transistor;
the fifth voltage stabilizing module comprises an eleventh transistor, a first electrode of the eleventh transistor is connected to the third node, a second electrode of the eleventh transistor is connected to the second node, and a control electrode of the eleventh transistor is connected to the first power signal end.

14. The shift register unit according to claim 1, wherein the control sub-circuit comprises a fourth control sub-module and a sixth voltage stabilizing module, wherein
wherein the fourth control sub-module is connected to the third node, the first node, a fifth node, the first power signal end, the second power signal end, the first clock signal end, the second clock signal end and the third clock signal end, and is configured to control signals of the first node and the fifth node and provide the signal of the third node to the first node or the fifth node in response to signals from the first power signal end, the second power signal end, the first clock signal end, the second clock signal end and the third clock signal end;
the sixth voltage stabilizing module is connected to the fifth node, the second node and the first power signal end, and is configured to provide a voltage of the fifth node to the second node in response to a signal from the first power signal end.

15. The shift register unit according to claim 14, wherein the fourth control sub-module comprises a first transistor, a sixth transistor, an eighth transistor, a ninth transistor, a tenth transistor, a third transistor, a seventh transistor, an eleventh transistor, a twelfth transistor, a first capacitor and a second capacitor; wherein
a first electrode of the first transistor is connected to the first clock signal end, a second electrode of the first transistor is connected to a sixth node, and a control electrode of the first transistor is connected to the third node;
a first electrode of the sixth transistor is connected to the first power signal end, a second electrode of the sixth transistor is connected to the sixth node, and a control electrode of the sixth transistor is connected to the first clock signal end;
a first electrode of the eighth transistor is connected to the sixth node, a second electrode of the eighth transistor is connected to a control electrode of the ninth transistor, and a control electrode of the eighth transistor is connected to the first power signal end;
a first electrode of the ninth transistor is connected to the second clock signal end, and a second electrode of the ninth transistor is connected to a first electrode of the tenth transistor;
a second electrode of the tenth transistor is connected to the first node, and a control electrode of the tenth transistor is connected to the second clock signal end;
a first electrode of the third transistor is connected to the second clock signal end, a second electrode of the third transistor is connected to a second electrode of the seventh transistor, and a control electrode of the third transistor is connected to the fifth node;
a first electrode of the seventh transistor is connected to the second power signal end, and a control electrode of the seventh transistor is connected to the sixth node;
a first electrode of the eleventh transistor is connected to the third node, a second electrode of the eleventh transistor is connected to the fifth node, and a control electrode of the eleventh transistor is connected to the first power signal end;
a first electrode of the twelfth transistor is connected to the third clock signal end, a second electrode of the twelfth transistor is connected to the first node, and a control electrode of the twelfth transistor is connected to the fifth node;
a first electrode of the first capacitor is connected to the fifth node, and a second electrode of the first capacitor is connected to the second electrode of the third transistor;
a first electrode of the second capacitor is connected to the control electrode of the ninth transistor, and a second electrode of the second capacitor is connected to the second electrode of the ninth transistor;
the sixth voltage stabilizing module comprises a seventeenth transistor, wherein a first electrode of the seventeenth transistor is connected to the fifth node, a second electrode of the seventeenth transistor is connected to the second node, and a control electrode of the seventeenth transistor is connected to the first power signal end.

16. The shift register unit according to claim 1, wherein the control sub-circuit comprises a fifth control sub-module and a seventh voltage stabilizing module, wherein
the fifth control sub-module is connected to the third node, a fourth node, the second node, the first power signal end, the second power signal end, the first clock signal end, the second clock signal end and the third clock signal end, and is configured to control signals of the fourth node and the second node and provide the signal of the third node to the fourth node or the second node in response to signals from the first power signal end, the second power signal end, the first clock signal end, the second clock signal end and the third clock signal end;
the seventh voltage stabilizing module is connected to the fourth node, the first node and the first power signal end, and is configured to provide a voltage of the fourth node to the first node in response to a signal from the first power signal end.

17. The shift register unit according to claim 16, wherein the fifth control sub-module comprises a first transistor, a sixth transistor, an eighth transistor, a ninth transistor, a tenth transistor, a third transistor, a seventh transistor, an eleventh transistor, a twelfth transistor, a first capacitor and a second capacitor; wherein
a first electrode of the first transistor is connected to the first clock signal end, a second electrode of the first transistor is connected to a sixth node, and a control electrode of the first transistor is connected to the third node;
a first electrode of the sixth transistor is connected to the first power signal end, a second electrode of the sixth transistor is connected to the sixth node, and a control electrode of the sixth transistor is connected to the first clock signal end;
a first electrode of the eighth transistor is connected to the sixth node, a second electrode of the eighth transistor is connected to a control electrode of the ninth transistor, and a control electrode of the eighth transistor is connected to the first power signal end;
a first electrode of the ninth transistor is connected to the second clock signal end, and a second electrode of the ninth transistor is connected to a first electrode of the tenth transistor;
a second electrode of the tenth transistor is connected to the fourth node, and a control electrode of the tenth transistor is connected to the second clock signal end;
a first electrode of the third transistor is connected to the second clock signal end, a second electrode of the third transistor is connected to a second electrode of the seventh transistor, and a control electrode of the third transistor is connected to the second node;
a first electrode of the seventh transistor is connected to the second power signal end, and a control electrode of the seventh transistor is connected to the sixth node;
a first electrode of the eleventh transistor is connected to the third node, a second electrode of the eleventh transistor is connected to the second node, and a control electrode of the eleventh transistor is connected to the first power signal end;
a first electrode of the twelfth transistor is connected to the third clock signal end, a second electrode of the twelfth transistor is connected to the fourth node, and a control electrode of the twelfth transistor is connected to the second node;
a first electrode of the first capacitor is connected to the second node, and a second electrode of the first capacitor is connected to the second electrode of the third transistor;
a first electrode of the second capacitor is connected to the control electrode of the ninth transistor, and a second electrode of the second capacitor is connected to the second electrode of the ninth transistor;
the seventh voltage stabilizing module comprises a sixteenth transistor, wherein a first electrode of the sixteenth transistor is connected to the fourth node, a second electrode of the sixteenth transistor is connected to the first node, and a control electrode of the sixteenth transistor is connected to the first power signal end.

18. A display panel, comprising:
a substrate, comprising a display area and a non-display area;
wherein the display area comprises:
sub-pixels;
scanning lines, wherein one row of the sub-pixels is coupled to at least one of the scanning lines;
wherein the non-display area comprises:
a gate driving circuit, comprising shift register units according to claim 1, wherein the driving output end of each of the shift register units is connected to at least one of the scanning lines; for two adjacent shift register units, the input signal end of a latter one of the shift register units is coupled to the cascade output end of a former one of the shift register units.

19. The display panel according to claim 18, further comprising control signal lines coupled to the gate driving circuit, wherein an extending direction of each of the control signal lines is same as an arrangement direction of the shift register units;
wherein an orthographic projection of the control signal lines on the substrate is located between an orthographic projection of the gate driving circuit on the substrate and the display area;
wherein the control signal lines comprise a first control sub-signal line and a second control sub-signal line; and the first control sub-signal line is coupled to the control signal ends of odd-numbered shift register units, and the second control sub-signal line is coupled to the control signal ends of even-numbered shift register units;
wherein the display panel further comprises auxiliary control signal lines, wherein an insulating layer is disposed between the auxiliary control signal lines and the control signal lines;
the auxiliary control signal lines are in one-to-one correspondence with the control signal lines, and the auxiliary control signal line and the corresponding control signal line are coupled to each other by holes penetrating through the insulating layer;
wherein the display panel further comprises clock signal lines, wherein an extending direction of each of the clock signal lines is same as the arrangement direction of the shift register units;
wherein the orthographic projection of the gate driving circuit on the substrate is located between an orthographic projection of the clock signal lines on the substrate and the orthographic projection of the control signal lines on the substrate;
wherein the display panel comprises a first clock signal line, a second clock signal line, a third clock signal line and a fourth clock signal line; wherein
wherein the first clock signal ends of odd-numbered shift register units and the second clock signal ends of even-numbered shift register units are coupled to the first clock signal line;
wherein the second clock signal ends of the odd-numbered shift register units and the first clock signal ends of the even-numbered shift register units are coupled to the second clock signal line;
wherein the third clock signal ends of the odd-numbered shift register units are coupled to the fourth clock signal line;
wherein the third clock signal ends of the even-numbered shift register units are coupled to the third clock signal line.

20-34. (canceled)

35. A display apparatus, comprising:
the display panel according to claim 18;
a driving control circuit, coupled to the display panel, and configured to input a first signal to the control signal ends of the shift register units when a full-screen refresh mode is determined to be adopted, so that the shift register units sequentially output gate scanning signals and drive the scanning lines row by row;
the driving control circuit is configured to input a second signal to the control signal ends of the shift register units when a partition refresh mode is determined to be adopted, so that part of the shift register units sequentially output gate scanning signals, and rest of the shift register units output invalid scanning signals.

36. A driving method for driving the display panel according to claim 18, comprising:
outputting a first signal to the control signal ends of the shift register units when a full-area refresh mode is determined to be adopted, so that the shift register units sequentially output gate scanning signals and drive the scanning lines row by row;
outputting a second signal to the control signal ends of the shift register units when a partition refresh mode is determined to be adopted, so that part of the shift register units sequentially output gate scanning signals, and rest of the shift register units output invalid scanning signals to drive part of the scanning lines.

37. The driving method according to claim 36, wherein the first signal is a clock signal.

38. The driving method according to claim 36, wherein the second signal comprises a fixed signal portion comprising a clock signal and a fixed signal portion comprising a second electrical level, the fixed signal portion comprising the clock signal is input into the part of the shift register units, and the fixed signal portion comprising the second electrical level is input into the rest of the shift register units.
